(19) United States
(12) Patent Application Publication
(10) Pub. No.: US 2026/0201087 A1
(43) Pub. Date: Jul. 16, 2026

(54) DICATIONIC POLYMER AND COPOLYMER AND THEIR USE FOR CHEMICAL MECHANICAL PLANARIZATION

(71) Applicant: Versum Materials US, LLC, Tempe, AZ (US)

(72) Inventors: Gregor Larbig, Gelnhausen (DE); Sana Ma, Phoenix, AZ (US)

(21) Appl. No.: 19/134,643

(22) PCT Filed: Nov. 30, 2023
(86) PCT No.: PCT/US2023/081792

§ 371 Date: May 30, 2025

Related U.S. Application Data
(60) Provisional application No. 63/387,137, filed on Dec. 13, 2022.

(51) Int. Cl. C08F 26/06; B24B 37/04; C09G 1/02; H10P 52/40

(52) U.S. Cl. CPC C08F 26/06; B24B 37/044; C09G 1/02; H10P 52/403

(57) ABSTRACT

Synthesis of dicationic polymer or copolymer is disclosed. The dicationic polymer or copolymer are formed by at least one dicationic (or dual-cationic) monomer. Chemical Mechanical Planarization (CMP) slurries comprise abrasives; activator, oxidizing agent; additive comprising dicationic polymer or copolymer; and water. The use of the synthesized dicationic polymer or copolymer in the CMP slurries reduces dishing and erosion in highly selective tungsten slurries.

### CROSS REFERENCE TO RELATED APPLICATION(S)

This application claims the benefit of U.S. Provisional Patent Application No. 63/387,137 filed on Dec. 13, 2022, which is incorporated herein by reference as if fully set forth.

### BACKGROUND OF THE INVENTION

The present disclosure relates to chemical mechanical planarization or polishing (“CMP”) slurries (or compositions, or formulations), polishing methods and polishing systems for carrying out chemical mechanical planarization in the production of a semiconductor device. In particular, the present disclosure relates to polishing slurries that are suitably used for polishing patterned semiconductor wafers that include metallic materials containing tungsten.

Chemical mechanical polishing or planarization (CMP) has been successfully used in the manufacturing process of integrated circuits for decades. It is considered as key and enabling technology for the downsizing demand.

Integrated circuits are interconnected through the use of well-known multilevel interconnections. Interconnection structures normally have a first layer of metallization, an interconnection layer, a second level of metallization, and typically third and subsequent levels of metallization. Interlevel dielectric materials such as silicon dioxide and sometimes low-k materials are used to electrically isolate the different levels of metallization in a silicon substrate or well. The electrical connections between different interconnection levels are made through the use of metallized vias and in particular tungsten vias. U.S. Pat. No. 4,789,648 describes a method for preparing multiple metallized layers and metallized vias in insulator films. In a similar manner, metal contacts are used to form electrical connections between interconnection levels and devices formed in a well. The metal vias and contacts are generally filled with tungsten and generally employ an adhesion layer such as titanium nitride (TiN) and/or titanium to adhere a metal layer such as a tungsten metal layer to the dielectric material.

In one semiconductor manufacturing process, metallized vias or contacts are formed by a blanket tungsten deposition followed by a CMP step. In a typical process, via holes are etched through the interlevel dielectric (ILD) to interconnection lines or to a semiconductor substrate. Next, a thin adhesion layer such as titanium nitride and/or titanium is generally formed over the ILD and is directed into the etched via hole. Then, a tungsten film is blanket deposited over the adhesion layer and into the via. The deposition is continued until the via hole is filled with tungsten. Finally, the excess tungsten is removed by CMP to form metal vias.

In another semiconductor manufacturing process, tungsten is used as a gate electrode material in the transistor because of its superior electrical characteristics over polysilicon which has been traditionally used as gate electrode material, as taught by A. Yagishita et al, IEEE TRANSACTIONS ON ELECTRON DEVICES, VOL. 47, NO. 5, May 2000.

In a typical CMP process, the substrate is placed in direct contact with a rotating polishing pad. A carrier applies pressure against the backside of the substrate. During the polishing process, the pad and table are rotated while a downward force is maintained against the substrate back. An abrasive and chemically reactive solution, commonly referred to as a polishing “slurry”, a polishing “composition” or a polishing “formulation”, is deposited onto the pad during polishing, where rotation and/or movement of the pad relative to the wafer brings said slurry into the space between the polishing pad and the substrate surface. The slurry initiates the polishing process by chemically reacting with the film being polished. The polishing process is facilitated by the rotational movement of the pad relative to the substrate as slurry is provided to the wafer/pad interface. Polishing is continued in this manner until the desired film on the insulator is removed. Removal of tungsten in the CMP is believed to be due to synergy between mechanical abrasion and tungsten oxidation followed by dissolution.

Despite its relatively simple outward appearance, chemical mechanical planarization (CMP) is a highly complex process as described by Lee Cook in digital Encyclopedia of Applied Physics, 2019, DOI: 10.1002/3527600434.eap847 10.1002/3527600434.eap847; and most of the time, CMP technology evolves faster than the understanding on which it is based as described by Seo, J. in Journal of Materials Research 2021, 36 (1), 235.1.

It's importance as enabling technology for past and future requirements for device scaling and new trends in semiconductor industry is undisputed. A multitude of interactions between wafer, slurry and pad as well as general process parameters determine the CMP outcome. Finally, material removal in CMP is the result of complex interaction between chemical and mechanical forces as described by Lee, D.; Lee, H.; Jeong, H. Slurry components in metal chemical mechanical planarization (CMP) process: A review. International Journal of Precision Engineering and Manufacturing 2016, 17, 1751. Large numbers of materials are used in semiconductor device fabrication, all of which require an optimized CMP process. Simultaneous polishing of combinations of completely different materials such as dielectric materials, barrier and metal layers is a real challenge with CMP.

One of the commonly encountered problems in CMP in particular in metal applications such as tungsten is how to control topological defects such as erosion and dishing. Smaller feature sizes and devices at the 7 nm node and beyond impose even stricter requirements on the acceptable extent of defects during polishing.

Highly selective slurries, which have a large difference in removal rate of metal versus rate of dielectric removal, are of great interest for future industry needs. However, there are imperfections associated with the use of these highly selective slurries. Metal layers can easily be over-polished, creating a “dishing” effect. Another unacceptable defect is called “erosion”, which describes topographical difference between an area with dielectric and a dense array of metal vias or trenches.

Specially designed water-based slurries are considered main drivers in improving CMP performance for future devices. The slurry developments not only affect the removal rate and selectivity between different layers, but also control defects during the polishing process. In general, the slurry composition is a complex combination of abrasives and chemical ingredients with different functions. As dispersants, passivation agents or generally as a topography-controlling additive, polymer additives play a key role in the slurry development to obtain the desired removal rates, selectivity and minimize surface imperfections by interacting with certain materials. For example, positively charged polymers inhibit tungsten removal and can be used to reduce dishing effects in tungsten CMP processes.

U.S. Pat. No. 5,876,490 describes the use of polish slurry comprising abrasive particles and exhibiting normal stress effect and further comprising polyelectrolyte having ionic moieties of a charge that differs from that associated with said abrasive particles and wherein the concentration of said polyelectrolyte is about 5 to about 50 percent by weight of said abrasive particles and wherein said polyelectrolyte has a molecular weight of about 500 to about 10,000.

U.S. Pat. No. 6,776,810 describes a chemical-mechanical polishing systems, and methods of polishing a substrate using the polishing systems, comprising (a) an abrasive, (b) a liquid carrier, and (c) a positively charged polyelectrolyte with a molecular weight of about 15,000 or more, wherein the abrasive comprises particles that are electrostatically associated with the positively charged electrolyte.

U.S. Pat. No. 7,247,567 provides a method of chemically-mechanically polishing a substrate comprising tungsten through use of a composition comprising a tungsten etchant, an inhibitor of tungsten etching, and water, wherein the inhibitor of tungsten polishing is a polymer, copolymer, or polymer blend comprising at least one repeating group comprising at least one nitrogen-containing heterocyclic ring or a tertiary or quaternary nitrogen atom. The invention further provides a chemical-mechanical polishing composition particularly useful in polishing tungsten-containing substrates.

US2010075501 describes a chemical mechanical polishing aqueous dispersion used to polish a polishing target that includes an interconnect layer that contains tungsten. The chemical mechanical polishing aqueous dispersion includes: (A) a cationic water-soluble polymer; (B) an iron (III) compound; and (C) colloidal silica particles. The content (M_{A}) (mass %) of the cationic water-soluble polymer (A) and the content (M_{B}) (mass %) of the iron (III) compound (B) satisfy the relationship “M_{A}/M_{B}=0.004 to 0.1”. The chemical mechanical polishing aqueous dispersion has a pH of 1 to 3.

US 2010/0252774 A1 describes a chemical mechanical polishing aqueous dispersion used to polish a polishing target that includes a wiring layer that contains tungsten. The chemical mechanical polishing aqueous dispersion includes: (A) a cationic water-soluble polymer; (B) an iron (III) compound; and (C) colloidal silica having an average particle diameter calculated from a specific surface area determined by the BET method of 10 to 60 nm. The content (M_{A}) (mass %) of the cationic water-soluble polymer (A) and the content (M_{C}) (mass %) of colloidal silica (C) satisfy the relationship “M_{A}/M_{C}=0.0001 to 0.003”. the chemical mechanical polishing aqueous dispersion.

U.S. Pat. No. 10,604,678 B1 discloses a process and a composition for polishing tungsten containing select quaternary phosphonium compounds at low concentrations to at least reduce corrosion rate of tungsten. The process and composition include providing a substrate containing tungsten, providing a stable polishing composition, containing, as initial components: water, an oxidizing agent: select quaternary phosphonium compounds at low concentrations to at least reduce corrosion rate: a dicarboxylic acid. a source of iron ions: a colloidal silica abrasive and optionally a pH adjusting agent; providing a chemical mechanical polishing pad, having a polishing surface; creating dynamic contact at an interface between the polishing pad and the substrate; and dispensing the polishing composition onto the polishing surface at or near the interface between the polishing pad and the substrate; wherein some of the tungsten is polished away from the substrate, and corrosion rate of tungsten is reduced.

US 2009/0081871 discloses a method comprising chemically-mechanically polishing a substrate with an inventive polishing composition comprising a liquid carrier, a cationic polymer, an acid, and abrasive particles that have been treated with an aminosilane compound.

US 2014/0248823 describes a chemical-mechanical polishing composition containing (a) abrasive particles, (b) a polymer, and (c) water, wherein (i) the polymer possesses an overall charge, (ii) the abrasive particles have a zeta potential Za measured in the absence of the polymer and the abrasive particles have a zeta potential Zb measured in the presence of the polymer, wherein the zeta potential Za is a numerical value that is the same sign as the overall charge of the polymer, and (iii) Izeta potential Zb|>|zeta potential Za|. The invention also provides a method of polishing a substrate with the polishing composition.

WO9905706 describes a chemical mechanical polishing composition and slurry comprising a composition capable of etching tungsten and at least one inhibitor of tungsten etching and methods for using the composition and slurry to polish tungsten containing substrates.

US20150259573 describes a chemical mechanical polishing composition for polishing a substrate having a tungsten layer includes a water based liquid carrier, a colloidal silica abrasive dispersed in the liquid carrier and having a permanent positive charge of at least 6 mV, and a polycationic amine compound in solution in the liquid carrier. A method for chemical mechanical polishing a substrate including a tungsten layer includes contacting the substrate with the above described polishing composition, moving the polishing composition relative to the substrate, and abrading the substrate to remove a portion of the tungsten from the substrate and thereby polish the substrate.

Cationic polymers of the imidazolium-type, polyionic liquids based on phosphonium groups, and triazole- or triazolium-based polymers have been identified and used in the CMP slurries in WO2022/246381, WO2022/261614, and WO2023/056324, respectively; which are entirely incorporated herein by reference.

One of the commonly encountered problems in CMP, particularly in metal applications such as tungsten, is dishing of tungsten lines and erosion of arrays of metal lines. Dishing and erosion are critical CMP parameters that define the planarity of the polished wafers. Dishing of lines typically increases for wider lines. Erosion of arrays typically increases with an increase in pattern density.

Tungsten CMP slurries must be formulated such that the dishing and erosion can be minimized in order to meet certain design targets critical for a functioning device.

Finding solutions to control topological defects such as erosion and dishing is key to future CMP requirements. There still has been a need for novel tungsten CMP slurries that can reduce dishing and erosion while maintain desirable removal rate in polishing.

### BRIEF SUMMARY OF THE INVENTION

The present invention satisfies the need by providing intelligent designed tungsten CMP slurries, systems, and methods of using the CMP slurries to minimize the described problem of dishing and erosion in highly selective tungsten slurries while maintain desirable polishing of metal layers, specifically tungsten films.

More specifically, the present invention discloses the synthesis of dicationic or dual-cationic polymers or copolymers.

The dicationic polymer or copolymer are formed by at least one first dicationic monomer. CMP slurries using the dicationic polymers have demonstrated to be able to reduce dishing and erosion and offer high selectivity in the removal rates of tungsten to TEOS or SiN.

In addition, several specific aspects of the present invention are outlined below.
Aspect 1: A dicationic polymer or copolymer formed by at least one dicationic monomer comprises a structure of (I):

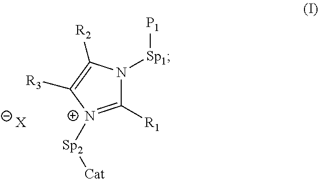

wherein:
P₁ denotes a polymerizable group;
Sp₁ and Sp₂ denote independently at each occurrence a spacer group or a single bond;
R₁, R₂, and R₃ are each independently H or substituted or unsubstituted aliphatic aromatic moiety selected from the group consisting of (1) alkyl having <12 C atoms, <6 C atoms, <4 C atoms or <2 C atoms; preferentially CH₃ or CH₂—CH₃; and (2) phenyl, pyridinyl, pyrimidyl, furanyl or any nitrogen-containing five-membered ring; preferentially pyridinyl or pyrimidyl; and (3) combinations of (1) and (2).
Cat denotes in each occurrence a cationic group; preferentially ammonium-, guanidinium-, triazolium-, phosphonium-, pyridinium- or triazolium-type.
X⁻ denotes an anionic counterion.
Aspect 2: A dicationic polymer or copolymer according to Aspect 1, wherein the polymerizable group P₁ is selected from groups containing C═C double bonds.
Aspect 3: A dicationic polymer or copolymer according to Aspects 1 to 2, wherein the anionic counterion is selected from the group consisting of halide (F—, Cl—, Br—, I—), BF₄—, PF₆—, carboxylate, malonate, citrate, carbonate, fumarate, MeOSO₃—, MeSO₃—, CF₃COO—, CF₃SO₃—, nitrate, or sulfate.
Aspect 4: A dicationic polymer or copolymer according to Aspects 1-3; wherein the dicationic polymer or copolymer is formed by a polymerization method selected from the group consisting of free radical polymerization, reversible addition-fragmentation chain-transfer polymerization (RAFT), nitroxide-mediated polymerization (NMP), atomic transfer reaction polymerization (ATRP), ring opening polymerization (ROMP) or polycondensation reaction.
Aspect 5: A dicationic polymer or copolymer according to Aspects 1-4; wherein the dicationic polymer or copolymer has a block-copolymer character.
Aspect 6: A chemical mechanical planarization composition comprising the dicationic polymer or copolymer according to Aspects 1 to 5.
Aspect 7: A chemical mechanical planarization composition comprising:
   an abrasive selected from the group consisting of inorganic oxide particles, metal oxide-coated inorganic oxide particles, organic polymer particles, metal oxide-coated organic polymer particles, and combinations thereof;
   an activator;
   an oxidizing agent;
   the dicationic polymer or copolymer according to Aspects 1 to 5;
   water; and optionally
   a corrosion inhibitor;
   a dishing reducing agent;
   a stabilizer;
   a pH adjusting agent.
Aspect 8: A system for chemical mechanical planarization, comprising:
   a semiconductor substrate comprising at least one surface containing tungsten;
   a polishing pad; and
   the chemical mechanical planarization composition according to Aspects 6 to 7;
   wherein the at least one surface containing tungsten is in contact with the polishing pad and the chemical mechanical planarization composition.
Aspect 9: A polishing method for chemical mechanical planarization of a semiconductor substrate comprising at least one surface containing tungsten, comprising the steps of:
   a) contacting the at least one surface containing tungsten with a polishing pad;
   b) delivering the chemical mechanical planarization composition of Aspects 6-7;
   c) polishing the at least one surface containing tungsten with the chemical mechanical planarization composition.

The abrasive includes, but is not limited to inorganic oxide particles, metal oxide-coated inorganic oxide particles, organic polymer particles, metal oxide-coated organic polymer particles, and combinations thereof.

The inorganic oxide particles include but are not limited to ceria, colloidal silica, high purity colloidal silica, fumed silica, colloidal ceria, alumina, titania, zirconia particles.

The metal oxide-coated inorganic oxide particles include but are not limited to the ceria-coated inorganic oxide particles, such as, ceria-coated colloidal silica, ceria-coated high purity colloidal silica, ceria-coated alumina, ceria-coated titania, ceria-coated zirconia, or any other ceria-coated inorganic oxide particles.

The organic polymer particles include, but are not limited to, polystyrene particles, polyurethane particle, polyacrylate particles, or any other organic polymer particles.

The metal oxide-coated organic polymer particles are selected from the group consisting of ceria-coated organic polymer particles, zirconia-coated organic polymer particles.

The concentration of abrasive can range from 0.01 wt. % to 30 wt. %, the preferred is from about 0.05 wt. % to about 20 wt. %, the more preferred is from about 0.01 to about 10 wt. %, and the most preferred is from 0.1 wt. % to 2 wt. %. The weight percent is relative to the composition.

The activator includes, but is not limited to (1) inorganic oxide particle with transition metal coated onto its surface; and the transition metal is selected from the group consisting of Fe, Cu, Mn, Co, Ce, and combinations thereof; (2) soluble catalyst selected from the group consisting of iron (III) nitrate, ammonium iron (III) oxalate trihydrate, iron (III) citrate tribasic monohydrate, iron (III) acetylacetonate and ethylenediamine tetraacetic acid, iron (III) sodium salt hydrate; (3) a metal compound having multiple oxidation states selected from the group consisting of Ag, Co, Cr, Cu, Fe, Mo, Mn, Nb, Ni, Os, Pd, Ru, Sn, Ti, V; and combinations thereof.

The activator ranges from 0.00001 wt. % to 5.0 wt. %, 0.0001 wt. % to 2.0 wt. %, 0.0005 wt. % to 1.0 wt. %, or 0.001 wt. % to 0.5 wt. %.

The oxidizing agent includes but is not limited to peroxy compound selected from the group consisting of hydrogen peroxide, urea peroxide, peroxyformic acid, peracetic acid, propaneperoxoic acid, substituted or unsubstituted butaneperoxoic acid, hydroperoxy-acetaldehyde, potassium periodate, ammonium peroxymonosulfate; and non-peroxy compound selected from the group consisting of ferric nitrite, KClO₄, KBrO₄, KMnO₄.

The oxidizer concentration can range from about 0.01 wt. % to 30 wt. % while the preferred concentration of oxidizing agents is from about 0.1 wt. % to 20 wt. %, and the more preferred concentration of oxidizing agents is from about 0.5 wt. % to about 10 wt. %. The weight percent is relative to the composition.

Examples of the dicationic polymer or copolymer include, but are not limited to poly(3-ethyl-1-(3-(1-vinyl-1 h-imidazol-3-ium-3-yl)propyl)-1 h-imidzaol-3-ium dibromide), poly(3-(tributylphosphino)propyl)-1-vinyl-1 h-imidzaol-3-ium dibromide), poly(3-(2-(trimethylammonio)ethyl)-1-vinyl-1 h-imidzaol-3-ium dibromide), and poly(3-(2-(trimethylammonio)ethyl)-1-vinyl-1 h-imidzaol-3-ium-co-n-vinyl-pyrrolidone dibromide).

The general amount of additive comprising dicationic polymers or copolymers ranges from 0.00001 wt. % to 1 wt. %, 0.0001 wt. % to 0.5 wt., 0.0005 wt. % to 0.1 wt. %, or 0.001 wt. % to 0.06 wt. %.

Suitable pH-adjusting agents to lower the pH of the polishing composition include, but are not limited to, nitric acid, sulfuric acid, tartaric acid, succinic acid, citric acid, malic acid, malonic acid, various fatty acids, various polycarboxylic acids and mixtures thereof. Suitable pH-adjusting agents to raise the pH of the polishing composition include, but are not limited to, potassium hydroxide, sodium hydroxide, ammonia, tetraethylammonium hydroxide, ethylenediamine, piperazine, polyethyleneimine, modified polyethyleneimine, and mixtures thereof.

The pH of the slurry is between 1 and 14, preferably is between 1 and 7, more preferably is between 1 and 6, and most preferably is between 1.5 and 4.

The CMP slurries may further comprise surfactant; dispersion agent; chelating agent; film-forming anticorrosion agent; and biocide.

Other aspects, features and embodiments of the invention will be more fully apparent from the ensuing disclosure and appended claims.

The embodiments of the invention can be used alone or in combinations with each other.

### DETAILED DESCRIPTION OF THE INVENTION

The present invention satisfies the need by providing intelligent designed tungsten CMP slurries, systems, and methods of using the CMP slurries to reduce the described problem of dishing and erosion in highly selective slurries while maintain desirable polishing of metal layers, specifically tungsten films.

Specific water-soluble cationic polymers have been used in tailor-made slurry formulations to reduce defects while enabling the desired removal rates and selectivity.

The present invention extends the general scope of application of cationic polymers to dicationic polymer or copolymer. Surprisingly, the dicationic polymer or copolymer has showed a significantly better suppression of erosion and dishing while maintaining the desired high removal rates and selectivity.

Among polymers used in CMP slurries, the disclosed dicationic polymer or copolymer are surprisingly not described as additives used in the CMP slurries.

The present invention discloses the synthesis of dicationic polymer or copolymer; and demonstrates the use of the synthesized dicationic polymer or copolymer in the CMP slurries to reduce the described problem of dishing and erosion in highly selective tungsten slurries.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention. The use of the term “comprising” in the specification and the claims includes the narrower language of “consisting essentially of” and “consisting of.”

Embodiments are described herein, including the best mode known to the inventors for carrying out the invention. Variations of those embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

For ease of reference, “microelectronic device” corresponds to semiconductor substrates, flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” is not meant to be limiting in any way and includes any substrate that will eventually become a microelectronic device or microelectronic assembly.

“Substantially free” is defined herein as less than 0.001 wt. %. “Substantially free” also includes 0.000 wt. %. The term “free of” means 0.000 wt. %.

As used herein, “about” is intended to correspond to +5%, preferably +2% of the stated value.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.00001 weight percent, based on the total weight of the composition in which such components are employed.

The CMP slurries in the present invention comprise dicationic polymer or copolymer.

More specifically, the CMP slurries comprise abrasive, dicationic polymer or copolymer, an oxidizing agent (i.e., an oxidizer that is not a free radical producer), an activator or catalyst, an additive, and water; optionally a corrosion inhibitor, a dishing reducing agent, a stabilizer, and a pH adjusting agent. The pH of the slurry is between 1 and 14, preferably is between 1 and 7, more preferably is between 1 and 6, and most preferably is between 1.5 and 4.

The CMP slurries may further comprise surfactant; dispersion agent; chelator; film-forming anticorrosion agent; biocide; and a polish enhancement agent.

### Abrasive

The abrasive used in CMP slurries includes, but is not limited to inorganic oxide particles, metal oxide-coated inorganic oxide particles, organic polymer particles, metal oxide-coated organic polymer particles, surface modified abrasive particles, and combinations thereof.

The abrasive used in CMP slurries can be activator-containing particles (i.e., an abrasive having an activator coating); or non-activator-containing particles.

The inorganic oxide particles include but are not limited to ceria, silica, alumina, titania, germania, spinel, an oxide or nitride of tungsten, zirconia particles, or any of the above doped with one or more other minerals or elements, and any combination thereof. The oxide abrasive may be produced by any of a variety of techniques, including sol-gel, hydrothermal, hydrolytic, plasma, pyrogenic, aerogel, fuming and precipitation techniques, and any combination thereof.

Precipitated inorganic oxide particles can be obtained by known processes by reaction of metal salts and acids or other precipitating agents. Pyrogenic metal oxide and/or metalloid oxide particles are obtained by hydrolysis of a suitable, vaporizable starting material in an oxygen/hydrogen flame. An example is pyrogenic silicon dioxide from silicon tetrachloride. The pyrogenic oxides of aluminum oxide, titanium oxide, zirconium oxide, silicon dioxide, cerium oxide, germanium oxide and vanadium oxide and chemical and physical mixtures thereof are suitable.

The metal oxide-coated inorganic oxide particles include but are not limited to the ceria-coated or alumina-coated inorganic oxide particles, such as, ceria-coated colloidal silica, alumina-coated colloidal silica, ceria-coated high purity colloidal silica, alumina-coated high purity colloidal silica, ceria-coated alumina, ceria-coated titania, alumina-coated titania, ceria-coated zirconia, alumina-coated zirconia, or any other ceria-coated or alumina-coated inorganic oxide particles.

The metal oxide-coated organic polymer particles are selected from the group consisting of ceria-coated organic polymer particles, zirconia-coated organic polymer.

The organic polymer particles include, but are not limited to, polystyrene particles, polyurethane particle, polyacrylate particles, or any other organic polymer particles.

Colloidal silica particles and high purify colloidal silica particles are the preferred abrasive particles. The silica can be any of precipitated silica, fumed silica, silica fumed, pyrogenic silica, silica doped with one or more adjutants, or any other silica based compound.

Colloidal silica particles and high purify colloidal silica particles being used as abrasives also include the surface chemically modified silica particles through chemical coupling reactions which allow such silica particle surface bearing different chemical functional groups and possess positive or negative charges at different applied pH conditions in CMP slurries. For example, amino-polyorganosiloxane-coated silica particles as disclosed in U.S. 63/269,585 filed on Mar. 18, 2022. The examples of such surface chemical modified silica particles include, but not limited to, SiO₂—R—NH₂, —SiO—R—SO₃M; wherein R can be for example, (CH₂)ₙ group with n ranged from 1 to 12, and M can be for example, sodium, potassium, or ammonium.

In an alternate embodiment the silica can be produced, for example, by a process selected from the group consisting of a sol-gel process, a hydrothermal process, a plasma process, a fuming process, a precipitation process, and any combination thereof.

The abrasive is generally in the form of an abrasive particle, and typically many abrasive particles, of one material or a combination of different materials. Generally, a suitable abrasive particle is more or less spherical and has an effective diameter of about 10 to 700 nm, about 20 to 500 nm, or about 30 to 300 nanometers (nm), although individual particle size may vary. The particle size can be measured by Dynamic Light Scattering (DLS). Abrasive in the form of aggregated or agglomerated particles are preferably processed further to form individual abrasive particles.

Abrasive particles may be purified using suitable method such as ion exchange to remove metal impurities that may help improve the colloidal stability. Alternatively, high purity abrasive particles are used.

In general, the above-mentioned abrasives may be used either alone or in combination with one another. It may be advantageous to have two or more abrasive particles with different sizes or different types of abrasives be combined to obtain excellent performance.

The concentration of abrasive can range from 0.01 wt. % to 30 wt. %, the preferred is from about 0.05 wt. % to about 20 wt. %, the more preferred is from about 0.01 to about 10 wt. %, and the most preferred is from 0.1 wt. % to 2 wt. %. The weight percent is relative to the composition.

0.05 wt. % to about 10 wt. %, the more preferred is from about 0.1 and about 2 wt. %.

### Additive

The CMP slurries of the present invention comprise additives that are the dicationic polymers or copolymers.
Yin, K. et al described the batteries using polyelectrolyte: “Polymer electrolytes based on dicationic polymeric ionic liquids: application in lithium metal batteries” in Journal of Materials Chemistry A 2015, 3 (1), 170.
Cao, W. et al described the porous membrane using polyelectrolyte “Dual-Cationic Poly(ionic liquid)s Carrying 1,2,4-Triazolium and Imidazolium Moieties: Synthesis and Formation of a Single-Component Porous Membrane” ACS Macro Letters 2021, 10 (1), 161.

Dual- or dicationic polymers or copolymers compared to polymers from the prior art have the increased charge density per molecular weight of the repeat unit; and combined different types of cations in the repeating unit which opens up new design possibilities.

Thus, the dicationic polymers or copolymers of the present invention have unique properties that help reduce erosion of highly selective metal CMP slurries.

Negatively charged polymers are generally able to interact electrostatically with oppositely charged surfaces such as positively charged tungsten surface. The use of optimized quantities and tailor-made polymers can thus greatly increase the selectivity between metal removal and the removal of oxide layers while reducing dishing effects.

At low pH values of <2.5, SiO₂ layers, as a classic standard oxide material, are by no means partially negatively charged.⁵ In other words, in order to block oxide erosion at the same time as metal dishing, the polymers used require are more tailored design that goes beyond the pure cationic approach.

Surprisingly, dicationic polymers or copolymers with a specific design have shown very low dishing and erosion behavior. This unique class of polymers can be used as topography-controlling additives and are valuable tools for designing next-generation slurries.

The dicationic polymer or copolymer formed by at least one dicationic monomer comprises a structure of (I):

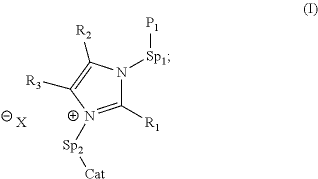

wherein:
P₁ denotes a polymerizable group;
Sp₁ and Sp₂ denote independently at each occurrence a spacer group or a single bond;
R₁, R₂, and R₃ are each independently H, or substituted or unsubstituted aliphatic aromatic moiety selected from the group consisting of (1) alkyl having <12 C atoms, <6 C atoms, <4 C atoms or <2 C atoms; preferentially CH₃ or CH₂—CH₃; and (2) phenyl, pyridinyl, pyrimidyl, furanyl or any nitrogen-containing five-membered ring; preferentially pyridinyl or pyrimidyl; and (3) combinations of (1) and (2);
Cat denotes in each occurrence a cationic group; preferentially ammonium-, guanidinium-, triazolium-, phosphonium-, pyridinium- or triazolium-type.
X⁻ denotes an anionic counterion.

The polymerizable group P₁ is selected from groups containing C═C double bonds.

The anionic counterion is selected from the group consisting of halide (F—, Cl—, Br—, I—), BF₄—, PF₆—, carboxylate, malonate, citrate, carbonate, fumarate, MeOSO₃—, MeSO₃—, CF₃COO—, CF₃SO₃—, nitrate, or sulfate.

The dicationic polymer or copolymer is formed by a polymerization method selected from the group consisting of free radical polymerization, reversible addition-fragmentation chain-transfer polymerization (RAFT), nitroxide-mediated polymerization (NMP), atomic transfer reaction polymerization (ATRP), ring opening polymerization (ROMP) or polycondensation reaction.

The dicationic polymer or copolymer according to Aspects 1-4; wherein the dicationic polymer or copolymer has a block-copolymer character.

Examples of the dicationic polymer or copolymer include, but are not limited to Poly(3-ethyl-1-(3-(1-vinyl-1H-imidazol-3-ium-3-yl)propyl)-1H-imidzaol-3-ium dibromide), Poly(3-(tributylphosphino)propyl)-1-vinyl-1H-imidzaol-3-ium dibromide), Poly(3-(2-(trimethylammonio)ethyl)-1-vinyl-1H-imidzaol-3-ium dibromide), and Poly(3-(2-(trimethylammonio)ethyl)-1-vinyl-1H-imidzaol-3-ium-co-N-vinyl-pyrrolidone dibromide).

The additive has a concentration ranging from about 0.00001 wt. % to 1.0 wt. %, about 0.0001 wt. % to 0.5 wt. %, about 0.00025 wt. % to 0.1 wt. %, or about 0.0005 wt. % to 0.05 wt. %.

### Oxidizing Agent

The CMP slurries of the present invention comprise an oxidizing agent or an oxidizer for chemical etching of material.

The oxidizing agent of the CMP slurry is in a fluid composition which contacts the substrate and assists in the chemical removal of targeted material on the substrate surface. The oxidizing agent component is thus believed to enhance or increase the material removal rate of the composition. Preferably, the amount of oxidizing agent in the composition is sufficient to assist the chemical removal process, while being as low as possible to minimize handling, environmental, or similar or related issues, such as cost.

Advantageously, in one embodiment of this invention, the oxidizer is a component which will, upon exposure to at least one activator, produce free radicals giving an increased etching rate on at least selected structures. The free radicals described infra will oxidize most metals and will make the surface more susceptible to oxidation from other oxidizers. However, oxidizers are listed separately from the “Compound Producing Free Radicals”, to be discussed infra, because some oxidizers do not readily form free radicals when exposed to the activators, and in some embodiments it is advantageous to have one or more oxidizers which provide matched etching or preferential etching rates on a variety of combinations of metals which may be found on a substrate.

As is known in the art, some oxidizers are better suited for certain components than for other components. In some embodiments of this invention, the selectivity of the CMP system to one metal as opposed to another metal is maximized, as is known in the art. However, in certain embodiments of present invention, the combination of oxidizers is selected to provide substantially similar CMP rates (as opposed to simple etching rates) for a conductor and a barrier combination.

In one embodiment, the oxidizing agent is an inorganic or organic per-compound.

A per-compound is generally defined as a compound containing an element in its highest state of oxidation, such as perchloric acid; or a compound containing at least one peroxy group (—O—O—), such as peracetic acid and perchromic acid.

Suitable per-compounds containing at least one peroxy group include, but are not limited to, peracetic acid or salt thereof, a percarbonate, and an organic peroxide, such as benzoyl peroxide, urea hydrogen peroxide, and/or di-t-butyl peroxide.

Suitable per-compounds containing at least one peroxy group include peroxides. As used herein, the term “peroxides” encompasses R—O—O—R′, where R and R′ are each independently H, a C₁ to C₆ straight or branched alkyl, alkanol, carboxylic acid, ketone (for example), or amine, and each of the above can independently be substituted with one or more benzyl group (for example benzoyl peroxide) which may themselves be substituted with OH or C₁-C₅ alkyls, and salts and adducts thereof. This term therefore includes common examples such as hydrogen peroxide, peroxyformic acid, peracetic acid, propaneperoxoic acid, substituted or unsubstituted butaneperoxoic acid, hydroperoxy-acetaldehyde, also encompassed in this term are common complexes of peroxides, for example urea peroxide.

Suitable per-compounds containing at least one peroxy group include persulfates. As used herein, the term “persulfates” encompasses monopersulfates, di-persulfates, and acids and salts and adducts thereof. Included for example is peroxydisulfates, peroxymonosulfuric acid and/or peroxymonosulfates, Caro's acid, including for example a salt such as potassium peroxymonosulfate, but preferably a non-metallic salt such as ammonium peroxymonosulfate.

Suitable per-compounds containing at least one peroxy group include perphosphates, defined as above and including peroxydiphosphates.

Also, ozone is a suitable oxidizing agent either alone or in combination with one or more other suitable oxidizing agents.

Suitable per-compounds that do not contain a peroxy group include, but are not limited to, periodic acid and/or any periodiate salt (hereafter “periodates”), perchloric acid and/or any perchlorate salt (hereafter “perchlorates”) perbromic acid and/or any perbromate salt (hereafter “perbromates”), and perboric acid and/or any perborate salt (hereafter “perbromates”).

Other oxidizing agents are also suitable components of the composition of the present invention. Iodates are useful oxidizers.

Two and more oxidizers may also be combined to obtain synergistic performance benefits.

In most embodiments of the present invention, the oxidizer is selected from the group consisting of peroxy compound selected from the group consisting of hydrogen peroxide, urea peroxide, peroxyformic acid, peracetic acid, propaneperoxoic acid, substituted or unsubstituted butaneperoxoic acid, hydroperoxy-acetaldehyde, potassium periodate, ammonium peroxymonosulfate; and non-per-oxy compound selected from the group consisting of ferric nitrite, KClO₄, KBrO₄, KMnO₄.

In some embodiments, the preferred oxidizer is hydrogen peroxide.

The oxidizer concentration can range from about 0.01 wt. % to 30 wt. % while the preferred concentration of oxidizing agents is from about 0.1 wt. % to 20 wt. %, and the more preferred concentration of oxidizing agents is from about 0.5 wt. % to about 10 wt. %. The weight percent is relative to the composition.

### Activator

An activator or a catalyst, is a material that interacts with an oxidizing agent and facilitates the formation of free radicals by at least one free radical-producing compounds present in the fluid.

The activator can be a metal-containing compound, in particular a metal selected from the group consisting of the metals known to activate a Fenton's Reaction process in the presence of an oxidizing agent such as, hydrogen peroxide.

The activator may be a non-metal-containing compound. Iodine is a useful with for example hydrogen peroxide to form free radicals.

If the activator is a metal ion, or metal-containing compound, it is in a thin layer associated with a surface of a solid which contacts the fluid. If the activator is a non-metal-containing substance, it can be dissolved in the fluid. It is preferred that the activator is present in amount that is sufficient to promote the desired reaction.

The activator includes, but is not limited to, (1) inorganic oxide particle with transition metal coated onto its surface, where the transition metal is selected from the group consisting of iron, copper, manganese, cobalt, cerium, and combinations thereof; (2) soluble catalyst includes, but is not limited to iron (III) nitrate, ammonium iron (III) oxalate trihydrate, iron (III) citrate tribasic monohydrate, iron (III) acetylacetonate and ethylenediamine tetraacetic acid, iron (III) sodium salt hydrate, a metal compound having multiple oxidation states selected from the group consisting of Ag, Co, Cr, Cu, Fe, Mo, Mn, Nb, Ni, Os, Pd, Ru, Sn, Ti, V; and combinations thereof.

The amount of activator in a slurry ranges from about 0.00001 wt. % to 5 wt. %, about 0.0001 wt. % to 2.0 wt. %, about 0.0005 wt. % to 1.0 wt. %; or about 0.001 wt. % to 0.5 wt. %.

### Water

The polishing compositions are aqueous based and, thus, comprise water. In the compositions, water functions in various ways such as, for example, to dissolve one or more solid components of the composition, as a carrier of the components, as an aid in the removal of polishing residue, and as a diluent. Preferably, the water employed in the cleaning composition is de-ionized (DI) water.

It is believed that, for most applications, water will comprise, for example, from about 10 to about 90% by weight or 90 wt. % of water. Other preferred embodiments could comprise from about 30 to about 95 wt. % of water. Yet other preferred embodiments could comprise from about 50 to about 90 wt. % % of water. Still other preferred embodiments could include water in an amount to achieve the desired weight percent of the other ingredients.

### Corrosion Inhibitor (Optional)

Corrosion inhibitors used in the CMP compositions disclosed herein include, but are not limited to, nitrogenous cyclic compounds such as 1,2,3-triazole, 1,2,4-triazole, 1,2,3-benzotriazole, 5-methylbenzotriazole, benzotriazole, 1-hydroxybenzotriazole, 4-hydroxybenzotriazole, 3-amino-1,2,4-triazole, 4-amino-4H-1,2,4-triazole, 5 amino triazole, benzimidazole, benzothiazoles such as 2,1,3-benzothiadiazole, triazinethiol, triazinedithiol, and triazinetrithiol, pyrazoles, imidazoles, isocyanurate such as 1,3,5-tris(2-hydroxyethyl), and mixtures thereof. Preferred inhibitors are 1,2,4-triazole, 5 amino triazole and 1,3,5-tris(2-hydroxyethyl) isocyanurate.

The amount of corrosion inhibitors in a slurry ranges from less than 1.0 wt. %, preferably less than 0.5 wt. %, or more preferably less than 0.25 wt. %.

### Dishing Reducing Agent (Optional)

The CMP composition may further comprise a dishing reducing agent or a dishing reducer selected from the group consisting of sarcosinate and related carboxylic compounds; hydrocarbon substituted sarcosinate; amino acids; organic polymers and copolymers having molecules containing ethylene oxide repeating units, such as polyethylene oxide (PEO); ethoxylated surfactants; nitrogen containing heterocycles without nitrogen-hydrogen bonds, sulfide, oxazolidine or mixture of functional groups in one compound; nitrogen containing compounds having three or more carbon atoms that form alkylammonium ions; amino alkyls having three or more carbon atoms; polymeric corrosion inhibitor comprising a repeating group of at least one nitrogen-containing heterocyclic ring or a tertiary or quaternary nitrogen atom; dicationic amine compound; cyclodextrin compound; polyethyleneimine compound; glycolic acid; chitosan; sugar alcohols; polysaccharides; alginate compound; sulfonic acid polymer. Glycine is a preferred dishing reducing agent.

Where the dishing reducing agent is present, the amount of dishing reducing agent ranges from about 0.001 wt. % to 2.0 wt. %, preferably 0.005 wt. % to 1.5 wt. %, and more preferably 0.01 wt. % to 1.5 wt. % based on weight per weight of the entire CMP composition.

### Stabilizers (Optional)

The composition may also include one or more of various optional additives. Suitable optional additives include stabilization agents. These optional additives are generally employed to facilitate or promote stabilization of the composition against settling, flocculation (including precipitation, aggregation or agglomeration of particles, and the like), and decomposition. Stabilizers can be used to extend the pot-life of the oxidizing agent(s), including compounds that produce free radicals, by isolating the activator material, by quenching free radicals, or by otherwise stabilizing the compounds that form free radicals.

Some materials are useful to stabilize hydrogen peroxide. One exception to the metal contamination is the presence of selected stabilizing metals such as tin. In some embodiments of this invention, tin can be present in small quantities, typically less than about 25 ppm, for example between about 3 and about 20 ppm. Similarly, zinc is often used as a stabilizer. In some embodiments of this invention, zinc can be present in small quantities, typically less than about 20 ppm, for example between about 1 and about 20 ppm. In another preferred embodiment the fluid composition contacting the substrate has less than 500 ppm, for example less than 100 ppm of dissolved metals, except for tin and zinc, having multiple oxidation states. In the most preferred commercial embodiments of this invention, the fluid composition contacting the substrate has less than 9 ppm of dissolved metals having multiple oxidation states, for example less than 2 ppm of dissolved metals having multiple oxidation states, except for tin and zinc. In some preferred embodiments of this invention, the fluid composition contacting the substrate has less than 50 ppm, preferably less than 20 ppm, and more preferably less than 10 ppm of dissolved total metals, except for tin and zinc.

As metals in solution are generally discouraged, it is preferred that those non-metal-containing oxidizers that are typically present in salt forms, for example persulfates, are in the acid form and/or in the ammonium salt form, such as ammonium persulfate.

Other stabilizers include free radical quenchers. As discussed, these will impair the utility of the free radicals produced. Therefore, it is preferred that if present they are present in small quantities. Most antioxidants, i.e., vitamin B, vitamin C, citric acid, and the like, are free radical quenchers. Most organic acids are free radical quenchers, but three that are effective and have other beneficial stabilizing properties are phosphonic acid, the binding agent oxalic acid, and the non-radical-scavenging sequestering agent gallic acid.

In addition, it is believed that carbonate and phosphate will bind onto the activator and hinder access of the fluid. Carbonate is particularly useful as it can be used to stabilize a slurry, but a small amount of acid can quickly remove the stabilizing ions. Stabilization agents useful for absorbed activator can be film forming agents forming films on the silica particle.

Suitable stabilizing agents include organic acids, such as adipic acid, phthalic acid, citric acid, malonic acid, orthophthalic acid; and phosphoric acid; substituted or unsubstituted phosphonic acids, i.e., phosphonate compounds; nitriles; and other ligands, such as those that bind the activator material and thus reduce reactions that degrade the oxidizing agent, and any combination of the foregoing agents. As used herein, an acid stabilizing agent refers to both the acid stabilizer and its conjugate base. That is, the various acid stabilizing agents may also be used in their conjugate form. By way of example, herein, an adipic acid stabilizing agent encompasses adipic acid and/or its conjugate base, a carboxylic acid stabilizing agent encompasses carboxylic acid and/or its conjugate base, carboxylate, and so on for the above mentioned acid stabilizing agents. A suitable stabilizer, used alone or in combination with one or more other stabilizers, decreases the rate at which an oxidizing agent such as hydrogen peroxide decomposes when admixed into the CMP slurry.

On the other hand, the presence of a stabilization agent in the composition may compromise the efficacy of the activator. The amount should be adjusted to match the required stability with the lowest adverse effect on the effectiveness of the CMP system. In general, any of these optional additives should be present in an amount sufficient to substantially stabilize the composition. The necessary amount varies depending on the particular additive selected and the particular make up of the CMP composition, such as the nature of the surface of the abrasive component. If too little of the additive is used, the additive will have little or no effect on the stability of the composition. On the other hand, if too much of the additive is used, the additive may contribute to the formation of undesirable foam and/or flocculant in the composition.

Generally, suitable amounts of these stabilizer range from about 0.0001 to 5 wt. % relative to the composition, preferably from about 0.00025 to 2 wt. %, and more preferably from about 0.0005 to about 1 wt. %. The stabilizer may be added directly to the composition or applied to the surface of the abrasive component of the composition.

### pH Adjusting Agent (Optional)

Compositions disclosed herein comprise pH adjusting agents. A pH adjusting agent is typically employed in the compositions disclosed herein to raise or lower the pH of the polishing composition. The pH-adjusting agent may be used to improve the stability of the polishing composition, to tune the ionic strength of the polishing composition, and to improve the safety in handling and use, as needed.

Suitable pH-adjusting agents to lower the pH of the polishing composition include, but are not limited to, nitric acid, sulfuric acid, tartaric acid, succinic acid, citric acid, malic acid, malonic acid, various fatty acids, various polycarboxylic acids and mixtures thereof. Suitable pH-adjusting agents to raise the pH of the polishing composition include, but are not limited to, potassium hydroxide, sodium hydroxide, ammonia, tetraethylammonium hydroxide, ethylenediamine, piperazine, polyethyleneimine, modified polyethyleneimine, and mixtures thereof.

When employed, the amount of pH-adjusting agent preferably ranges from about 0.01 wt. % to about 5.0 wt. % relative to the total weight of the polishing composition. The preferred range is from about 0.01 wt. % to about 1 wt. % or from about 0.05 wt. % to about 0.15 wt. %.

The pH of the slurry is between 1 and 14, preferably is between 1 and 7, more preferably is between 1 and 6, and most preferably is between 1.5 and 4.

### Surfactant (Optional)

The compositions disclosed herein optionally comprise a surfactant, which, in part, aids in protecting the wafer surface during and after polishing to reduce defects in the wafer surface. Surfactants may also be used to control the removal rates of some of the films used in polishing such as low-K dielectrics. Suitable surfactants include non-ionic surfactants, anionic surfactants, cationic surfactants, ampholytic surfactants, and mixtures thereof.

Non-ionic surfactants may be chosen from a range of chemical types including but not limited to long chain alcohols, ethoxylated alcohols, ethoxylated acetylenic diol surfactants, polyethylene glycol alkyl ethers, propylene glycol alkyl ethers, glucoside alkyl ethers, polyethylene glycol octylphenyl ethers, polyethylene glycol alkylphenyl ethers, glycerol alkyl esters, polyoxyethylene glycol sorbiton alkyl esters, sorbiton alkyl esters, cocamide monoethanol amine, cocamide diethanol amine dodecyl dimethylamine oxide, block-copolymers of polyethylene glycol and polypropylene glycol, polyethoxylated tallow amines, fluorosurfactants.

The molecular weight of surfactants may range from several hundreds to over 1 million. The viscosities of these materials also possess a very broad distribution.

Anionic surfactants include, but are not limited to salts with suitable hydrophobic tails, such as alkyl carboxylate, alkyl polyacrylic salt, alkyl sulfate, alkyl phosphate, alkyl bicarboxylate, alkyl bisulfate, alkyl biphosphate, such as alkoxy carboxylate, alkoxy sulfate, alkoxy phosphate, alkoxy bicarboxylate, alkoxy bisulfate, alkoxy biphosphate, such as substituted aryl carboxylate, substituted aryl sulfate, substituted aryl phosphate, substituted aryl bicarboxylate, substituted aryl bisulfate, and substituted aryl biphosphate etc. The counter ions for this type of surfactants include, but are not limited to potassium, ammonium and other positive ions. The molecular weights of these anionic surface wetting agents range from several hundred to several hundred-thousand.

Cationic surfactants possess the positive net charge on major part of molecular frame. Cationic surfactants are typically halides of molecules comprising hydrophobic chain and cationic charge centers such as amines, quaternary ammonium, benzyalkonium, and alkylpyridinium ions.

In another aspect, the surfactant can be an ampholytic surfactant, which possess both positive (cationic) and negative (anionic) charges on the main molecular chains and with their relative counter ions. The cationic part is based on primary, secondary, or tertiary amines or quaternary ammonium cations. The anionic part can be more variable and include sulfonates, as in the sultaines CHAPS (3-[(3-Cholamidopropyl)dimethylammonio]-1-propanesulfonate) and cocamidopropyl hydroxysultaine. Betaines such as cocamidopropyl betaine have a carboxylate with the ammonium. Some of the ampholytic surfactants may have a phosphate anion with an amine or ammonium, such as the phospholipids phosphatidylserine, phosphatidylethanolamine, phosphatidylcholine, and sphingomyelins.

Examples of surfactants also include, but are not limited to, dodecyl sulfate sodium salt, sodium lauryl sulfate, dodecyl sulfate ammonium salt, secondary alkane sulfonates, alcohol ethoxylate, acetylenic surfactant, and any combination thereof. Examples of suitable commercially available surfactants include TRITON™, Tergitol™, DOWFAX™ family of surfactants manufactured by Dow Chemicals and various surfactants in SURFYNOL™, DYNOL™, Zetasperse™, Nonidet™, and Tomadol™ surfactant families, manufactured by Air Products and Chemicals. Suitable surfactants of surfactants may also include polymers comprising ethylene oxide (EO) and propylene oxide (PO) groups. An example of EO-PO polymer is Tetronic™ 90R4 from BASF Chemicals.

When employed, the amount of surfactant typically ranges from 0.0001 wt. % to about 1.0 wt. % relative to the total weight of the barrier CMP composition. When employed, the preferred range is from about 0.010 wt. % to about 0.1 wt. %.

### Chelating Agent (Optional)

Chelating agents may optionally be employed in the compositions disclosed herein to enhance affinity of chelating ligands for metal cations. Chelating agents may also be used to prevent build-up of metal ions on pads which causes pad staining and instability in removal rates. Suitable chelating agents include, but are not limited to, for example, amine compounds such as ethylene diamine, amino poly-carboxylic acids such as ethylene diamine tetraacetic acid (EDTA), nitrilotriacetic acid (NTA); aromatic acids such as benzenesulfonic acid, 4-tolyl sulfonic acid, 2,4-diamino-benzosulfonic acid, and etc.; non-aromatic organic acids, such as itaconic acid, malic acid, malonic acid, tartaric acid, citric acid, oxalic acid, gluconic acid, lactic acid, mandelic acid, or salts thereof; various amino acids and their derivatives such as Glycine, Serine, Proline, Histidine, Isoleucine, Leucine, Lysine, Methionine, Phenylalanine, Threonine, Tryptophan, Valine, Arginine, Asparagine, Aspartic acid, cystein, Glutamic acid, Glutamine, Ornithine, Selenocystein, Tyrosine, Sarcosine, Bicine, Tricine, Aceglutamide, N-Acetylaspartic acid, Acetylcarnitine, Acetylcysteine, N-Acetylglutamic acid, Acetylleucine, Acivicin, S-Adenosyl-L-homocysteine, Agaritine, Alanosine, Aminohippuric acid, L-Arginine ethyl ester, Aspartame, Aspartylglucosamine, Benzylmercapturic acid, Biocytin, Brivanib alaninate, Carbocisteine, N(6)-Carboxymethyllysine, Carglumic acid, Cilastatin, Citiolone, Coprine, Dibromotyrosine, Dihydroxyphenylglycine, Eflornithine, Fenclonine, 4-Fluoro-L-threonine, N-Formylmethionine, Gamma-L-Glutamyl-L-cysteine, 4-(γ-Glutamylamino)butanoic acid, Glutaurine, Glycocyamine, Hadacidin, Hepapressin, Lisinopril, Lymecycline, N-Methyl-D-aspartic acid, N-Methyl-L-glutamic acid, Milacemide, Nitrosoproline, Nocardicin A, Nopaline, Octopine, Ombrabulin, Opine, Orthanilic acid, Oxaceprol, Polylysine, Remacemide, Salicyluric acid, Silk amino acid, Stampidine, Tabtoxin, Tetrazolylglycine, Thiorphan, Thymectacin, Tiopronin, Tryptophan tryptophylquinone, Valaciclovir, Valganciclovir, and phosphonic acid and its derivatives such as, for example, octylphosphonic acid, aminobenzylphosphonic acid, and combinations thereof and salts thereof.

Chelating agents may be employed where there is a need to chemically bond, for example, copper cations and tantalum cations to accelerate the dissolution of copper oxide and tantalum oxide to yield the desirable removal rates of copper lines, vias, or trenches and barrier layer, or barrier films.

When employed, the amount of chelating agent preferably ranges from about 0.01 wt. % to about 3.0 wt. % relative to the total weight of the composition and, more preferably, from about 0.4 wt. % to about 1.5 wt. %.

### Biocide (Optional)

CMP formulations disclosed herein may also comprise additives to control biological growth such as biocides. Some of the additives to control biological growth are disclosed in U.S. Pat. No. 5,230,833 and U.S. patent application Publication No. 2002/0025762, which is incorporated herein by reference. Biological growth inhibitors include but are not limited to tetramethylammonium chloride, tetraethylammonium chloride, tetrapropylammonium chloride, alkylbenzyldimethylammonium chloride, and alkylbenzyldimethylammonium hydroxide, wherein the alkyl chain ranges from 1 to about 20 carbon atoms, sodium chlorite, sodium hypochlorite, isothiazolinone compounds such as methylisothiazolinone, methylchloroisothiazolinone and benzisothiazolinone. Some of the commercially available preservatives include KATHON™ and NEOLENE™ product families from Dow Chemicals and Preventol™ family from Lanxess.

The preferred biocides are isothiozilone compounds such as methylisothiazolinone, methylchloroisothiazolinone and benzisothiazolinone.

The CMP polishing compositions optionally contain a biocide ranging from 0.0001 wt. % to 0.10 wt. %, preferably from 0.0001 wt. % to 0.005 wt. %, and more preferably from 0.0002 wt. % to 0.0025 wt. % to prevent bacterial and fungal growth during storage.

Compositions disclosed herein may be manufactured in a concentrated form and subsequently diluted at the point of use with DI water. Other components such as, for example, the oxidizer, may be withheld in the concentrate form and added at the point of use to minimize incompatibilities between components in the concentrate form. The compositions disclosed herein may be manufactured in two or more components which can be mixed prior to use.

### WORKING EXAMPLES

### General Experimental Procedure

All percentages are weight percentages unless otherwise indicated.

### Part I Synthesis of a Dicationic Polymer or Copolymer

All reagents and solvents were purchased from Sigma-Aldrich (Merck) of highest commercial grade and used as received unless otherwise specified.

### Characterization Methods

NMR spectra were recorded on a 500 MHz Bruker Avance II+ spectrometer using deuterated solvents from Sigma-Aldrich (Merck). Chemical shifts were reported as d values (ppm) and were calibrated according to internal standard Si(OMe)₄ (0.00 ppm).

Polycationic polymers were analyzed by size exclusion chromatography (SEC) running in H₂O/MeOH/EtOAc (54/23/23, v/v/v) containing 10 mM sodium acetate at 40° C. (flow rate: 0.5 mL/min). Measurements were carried out on an Agilent 1260 HPLC, equipped with a column set consisting of PSS Novema pre-column and PSS Novema MAX ultraheigh column. The samples were dissolved in the eluent with 0.1% ethylenglycol as internal standard at 50° C. The average molar mass of polymers was derived from refractive index signals based on poly(2-vinylpyridine) calibration curve.

### Example 1: Poly(3-ethyl-1-(3-(1-vinyl-1H-imidazol-3-ium-3-yl)propyl)-1H-imidzaol-3-ium dibromide)

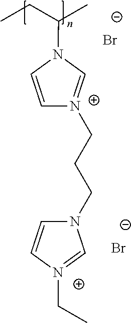

### Monomer Synthesis:

### Synthesis of 3-(3-bromopropyl)-1-vinyl-1H-imidazol-3-ium

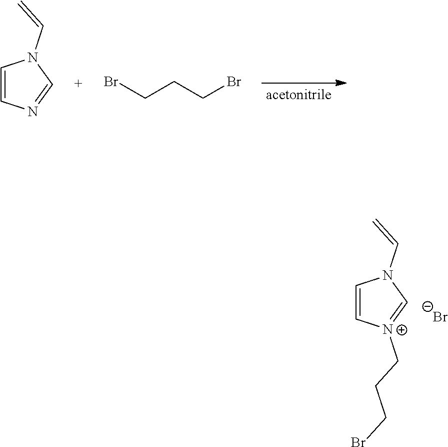

1,3-Dibromopropane (CAS: 109-64-8, 107 mL, 1.06 mol) was dissolved in acetonitrile (300 mL) and then added dropwise with 1-vinyl-imidazole (CAS: 1072-63-5, 10 g, 0.105 mol dissolved in 40 mL acetonitrile) at room temperature while stirring. The reaction mixture was heated at 65° C. overnight, allowed to cool to room temperature, and ethyl acetate (1 L) was added, wherein the crude product precipitates as oil. The mixture was concentrated under vacuum and finally purified by column chromatography (silica gel, DCM/MeOH 95:5) to yield 21.7 g (70%) of a pale yellow solid.

¹H NMR (500 MHz, DMSO-d6) δ=9.62 (t, J=1.6 Hz, 1H), 8.25 (t, J=1.9 Hz, 1H), 7.98 (t, J=1.9 Hz, 1H), 7.32 (dd, J=15.6, 8.7 Hz, 1H), 5.99 (dd, J=15.6, 2.4 Hz, 1H), 5.43 (dd, J=8.8, 2.4 Hz, 1H), 4.34 (t, J=7.0 Hz, 2H), 3.58 (t, J=6.6 Hz, 2H), 2.41 (p, J=6.8 Hz, 2H) ppm.

### Synthesis of 3-ethyl-1-(3-(1-vinyl-1H-imidazol-3-ium-3-yl)propyl)-1H-imidzaol-3-ium dibromide)

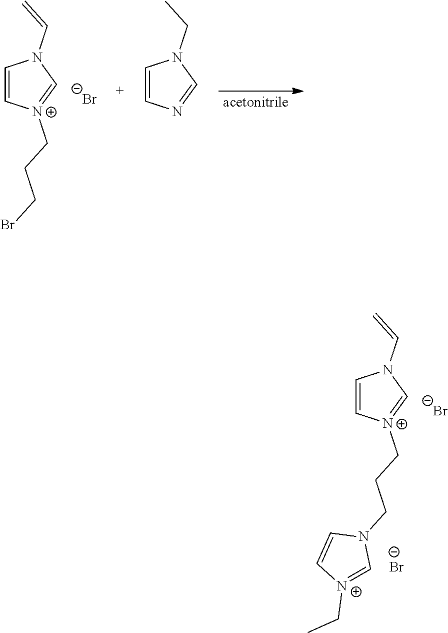

3-(3-bromopropyl)-1-vinyl-1H-imidazol-3-ium (4.7 g, 16 mmol) was dissolved in 40 mL acetonitrile and added at room temperature while stirring dropwise with N-ethylimidazole (CAS: 7098-07-9; 1.9 g, 19 mmol dissolved in 10 mL acetonitrile). The reaction mixture was heated overnight at 60° C., allowed to cool to room temperature. and mixed with ethyl acetate (500 mL), wherein an oil was precipitated. The oil was washed with ethyl acetate, dissolved in water and freeze-dried resulting 5.7 g (92%) of a solid.

¹H NMR (500 MHz, DMSO-d6) δ=9.75 (d, J=1.6 Hz, 1H), 9.40 (t, J=1.7 Hz, 1H), 8.28 (t, J=1.9 Hz, 1H), 8.03 (t, J=1.8 Hz, 1H), 7.88 (d, J=1.6 Hz, 2H), 7.35 (dd, J=15.7, 8.7 Hz, 1H), 6.02 (dd, J=15.6, 2.4 Hz, 1H), 5.45 (dd, J=8.8, 2.4 Hz, 1H), 4.31 (dt, J=12.2, 6.9 Hz, 4H), 4.23 (q, J=7.3 Hz, 2H), 2.53-2.45 (m, 2H), 1.44 (t, J=7.3 Hz, 3H) ppm.

### Polymerization:

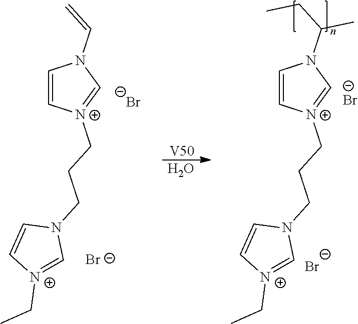

3-Ethyl-1-(3-(1-vinyl-1H-imidazol-3-ium-3-yl)propyl)-1H-imidzaol-3-ium dibromide) (5.7 g, 14.5 mmol) was dissolved in water (30 mL), 1,2′-azobis(2-methylpropionamidine) dhihydrochloride (V50, CAS: 2997-92-4, 18.5 mg, 0.068 mmol) was added, the mixture was purged with argon for 30 min and then heated overnight at reflux. The solution was allowed to cool to r.t. and then mixed with THF (250 mL), precipitating an oil that was dissolved in water and purified by cross-flow filtration (MWCO: 5 kDa). The purified polymer was freeze-dried so that 3.15 g (55%) of a white solid was obtained.

¹H NMR (500 MHz, DMSO-d6) δ=10.00 (broad s), 9.68 (broad s), 8.07 (broad s), 7.96 (broad s), 4.69 (broad s), 4.42 (broad s), 4.26 (broad s), 2.63 (broad s), 2.05 (broad s), 1.46 (broad s) ppm.

SEC: Mn: 19.0 kDa; Mw: 41.1 kDa; PDI: 2.1.

### Example 2: Poly(3-(tributylphosphino)propyl)-1-vinyl-1H-imidzaol-3-ium dibromide)

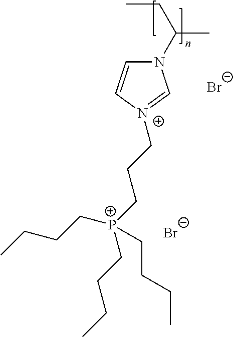

### Monomer Synthesis:

Synthesis of 3-(3-bromopropyl)-1-vinyl-1H-imidazol-3-ium according to the same method described for Example 1.

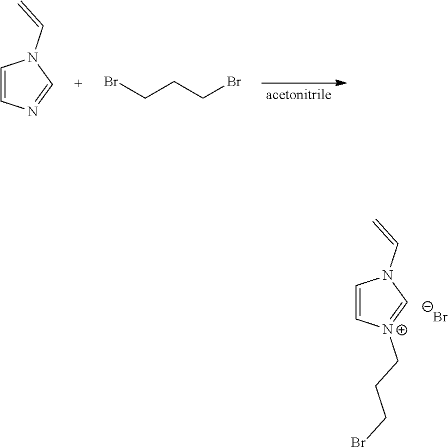

### Synthesis of 3-(tributylphosphino)propyl-1-vinyl-1H-imidzaol-3-ium dibromide

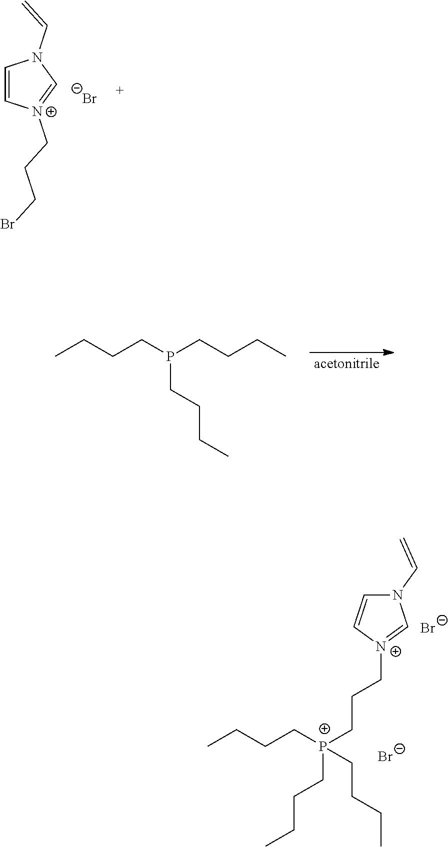 [SMILES: C=Cn1cc[n+](CCCBr)c1 ; [Br-] ; CCCCP(CCCC)CCCC ; C=Cn1cc[n+](CCC[P+](CCCC)(CCCC)CCCC)c1 ; [Br-] ; [Br-]]

3-(3-bromopropyl)-1-vinyl-1H-imidazol-3-ium (5.5 g, 18.6 mmol) was dissolved in 40 mL acetonitrile and added at room temperature while stirring dropwise with tributylphosphine (CAS: 998-40-3; 4.1 g, 20 mmol dissolved in 10 mL acetonitrile). The reaction mixture was heated overnight at 60° C., allowed to cool to r.t. and mixed with tert-butyl methyl ether (MTBE, 500 mL), wherein a solid was precipitated. The crude product was washed with MTBE and vacuum-dried resulting 8 g (71%) of a colorless solid.

¹H NMR (500 MHz, DMSO-d6) δ=9.76 (t, J=1.6 Hz, 1H), 8.29 (t, J=1.9 Hz, 1H), 8.06 (t, J=1.8 Hz, 1H), 7.37 (dd, J=15.6, 8.8 Hz, 1H), 6.03 (dd, J=15.6, 2.4 Hz, 1H), 5.46 (dd, J=8.7, 2.4 Hz, 1H), 4.35 (t, J=6.9 Hz, 2H), 2.38-2.26 (m, 1H), 2.32 (s, 1H), 2.29-2.21 (m, 6H), 2.16 (dq, J=12.4, 7.4 Hz, 2H), 1.53-1.36 (m, 12H), 0.92 (t, J=7.1 Hz, 9H) ppm.

### Polymerization:

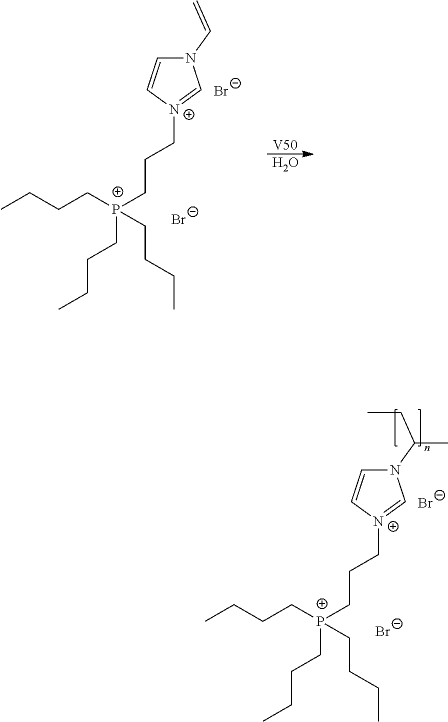

3-(Tributylphosphino)propyl-1-vinyl-1H-imidzaol-3-ium dibromide (6 g, 12.4 mmol) was dissolved in water (30 mL), 1,2′-azobis(2-methylpropionamidine) dhihydrochloride (V50, CAS: 2997-92-4, 13.9 mg, 0.05 mmol) was added, the mixture was purged with argon for 30 min and then heated overnight at reflux. The solution was allowed to cool to r.t. and then purified by cross-flow filtration (MWCO: 3 kDa). The purified polymer was freeze-dried so that 2.1 g (35%) of a white solid was obtained.

¹H NMR (500 MHz, DMSO-d6) δ=10.00 (broad s), 8.44 (broad s), 4.54 (broad s), 2.22 (broad s), 1.54 (broad s), 1.43 (broad s), 0.93 (broad s) ppm.

SEC: Mn: 11.0 kDa; Mw: 22.3 kDa; PDI: 2.0.

### Example 3: Poly(3-(2-(trimethylammonio)ethyl)-1-vinyl-1H-imidzaol-3-ium dibromide)

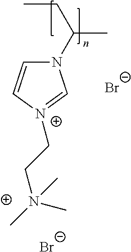

### Monomer Synthesis:

### Synthesis of 3-(2-(trimethylammonio)ethyl)-1-vinyl-1H-imidazol-3-ium dibromide

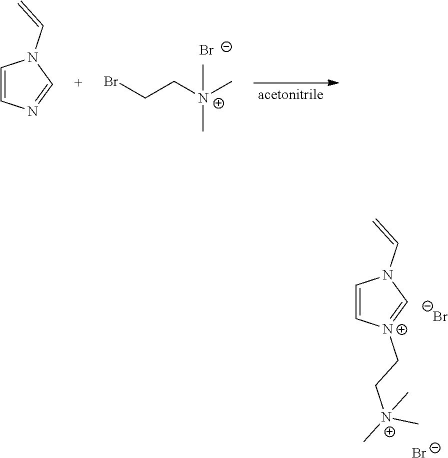

(2-Bromoethyl)trimethylammonium bromide (CAS: 2758-06-7, 25 g, 101 mmol) was dissolved in 150 mL acetonitrile and added at room temperature while stirring dropwise with 1-vinylimidazole (CAS: 1072-63-3; 10.7 g, 112.5 mmol). The reaction mixture was heated overnight at 60° C., allowed to cool to r.t. and mixed with ethyl acetate (500 mL), wherein an oil was precipitated. The crude product was washed with ethyl acetate, dissolved in water and freeze-dried resulting 32.7 g (85%) of a colorless solid.

¹H NMR (500 MHz, DMSO-d6) δ=9.60 (t, J=1.6 Hz, 1H), 8.18 (t, J=1.9 Hz, 1H), 8.00 (t, J=1.9 Hz, 1H), 7.29 (dd, J=15.6, 8.6 Hz, 1H), 5.95 (dd, J=15.6, 2.6 Hz, 1H), 5.46 (dd, J=8.7, 2.6 Hz, 1H), 4.82 (t, J=7.1 Hz, 2H), 3.98 (t, J=7.1 Hz, 2H), 3.19 (s, 9H) ppm.

### Polymerization:

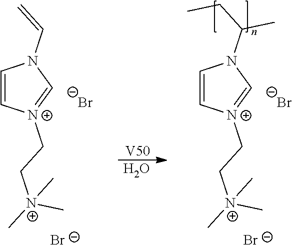

3-(2-(trimethylammonio)ethyl)-1-vinyl-1H-imidazol-3-ium dibromide (5 g, 14.8 mmol) was dissolved in water (30 mL), 1,2′-azobis(2-methylpropion-amidine) dhihydrochloride (V50, CAS: 2997-92-4, 13.6 mg, 0.05 mmol) was added, the mixture was purged with argon for 30 min and then heated overnight at reflux. The solution was allowed to cool to r.t. and then mixed with THF (250 mL), precipitating an oil that was dissolved in water and purified by cross-flow filtration (MWCO: 5 kDa). The purified polymer was freeze-dried so that 4.7 g (94%) of a white solid was obtained.

¹H NMR (500 MHz, DMSO-d6) δ=9.79 (broad s), 8.15 (broad s), 8.01 (broad s), 4.88 (broad s), 4.29 (broad s), 3.3 (broad s), 2.63 (broad s) ppm.

SEC: Mn: 24 kDa; Mw: 73 kDa; PDI: 3.0

### Example 4: Poly(3-(2-(trimethylammonio)ethyl)-1-vinyl-1H-imidzaol-3-ium-co-N-vinyl-pyrrolidone dibromide)

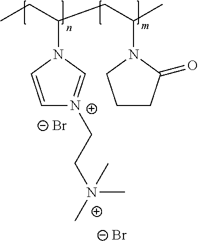

### Monomer Synthesis:

### Synthesis of 3-(2-(trimethylammonio)ethyl)-1-vinyl-1H-imidazol-3-ium dibromide

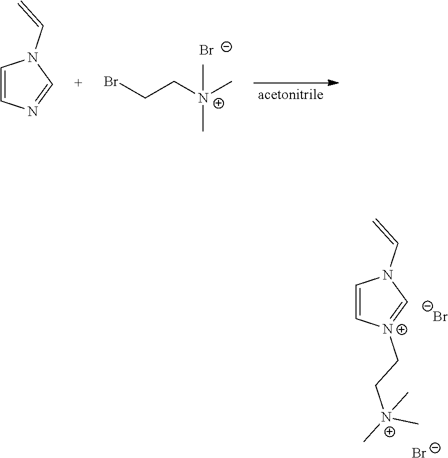

The same method was used as described in Example 3.

### Polymerization Example 4-1

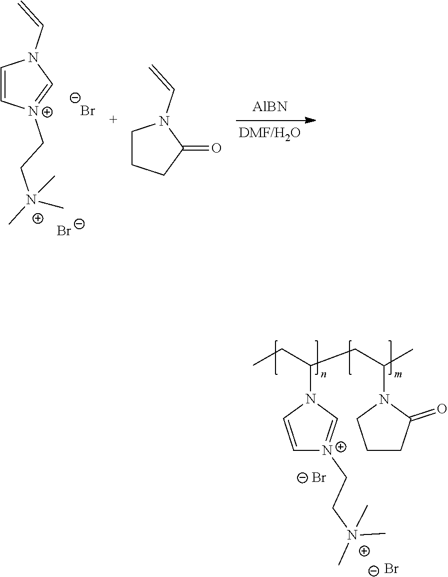

3-(2-(trimethylammonio)ethyl)-1-vinyl-1H-imidazol-3-ium dibromide (4 g, 11.7 mmol) and 1-vinyl-2-pyrrolidone (CAS: 88-12-0, 3.9 g, 35.2 mmol) were dissolved in DMF/water (1:1, 60 mL) and mixed with 2,2′-azobisisobutynonitrile (AIBN, CAS: 78-67-1, 13.3 mg, 0.08 mmol). The mixture was purged with argon for 30 min and then heated overnight at reflux. The solution was allowed to cool to r.t. and mixed with ethyl acetate (500 mL), precipitating an oil that was dissolved in water and purified by cross-flow filtration (MWCO: 10 kDa). The purified polymer was freeze-dried so that 3.8 g (48%) of a white solid was obtained.

¹H NMR (500 MHz, DMSO-d6) δ=9.71 (broad s), 8.13 (broad s), 4.84 (broad s), 4.03 (broad s), 3.61 (broad s), 3.26 (broad s), 2.37 (broad s), 1.90 (broad s) ppm.

SEC: Mn: 35 kDa; Mw: 119 kDa; PDI: 3.4

### Polymerization Example 4-2

The same method was used as described in Example 4-1 but using 11.7 g (105.5 mmol) of 1-vinyl-2-pyrrolidone (CAS: 88-12-0). The purified polymer was freeze-dried so that 8.8 g (56%) of a white solid was obtained.

¹H NMR (500 MHz, DMSO-d6) δ: 9.71 (broad s), 8.05 (broad s), 7.76 (broad s), 4.80 (broad s), 4.01 (broad s), 3.74 (broad s), 3.54 (broad s), 3.22 (broad s), 2.27 (broad s), 2.09 (broad s), 1.90 (broad s), 1.62 (broad s), 1.31 (broad s) ppm.

SEC: Mn: 41 kDa; Mw: 272 kDa; PDI: 6.6

### Polymerization Example 4-3

The same method was used as described in Example 4-1 but using 2 g (5.9 mmol) of 3-(2-(trimethylammonio)ethyl)-1-vinyl-1H-imidazol-3-ium and 12.4 g (111 mmol) of 1-vinyl-2-pyrrolidone (CAS: 88-12-0). The purified polymer was freeze-dried so that 10.3 g (72%) of a white solid was obtained.

¹H NMR (500 MHz, DMSO-d6) δ: 9.46 (broad s), 8.01 (broad s), 7.70 (broad s), 4.78 (broad s), 3.95 (broad s), 3.75 (broad s), 3.56 (broad s), 3.19 (broad s), 2.07 (broad s), 1.87 (broad s), 1.63 (broad s), 1.32 (broad s) ppm.

SEC: Mn: 29 kDa; Mw: 207 kDa; PDI: 7.0.

### Part II CMP Experiments

### Using Synthesized Phosphonium-Based Polymers in Part I

The polishing composition and associated methods described herein are effective for CMP of a wide variety of substrates, including most of substrates, particularly useful for polishing tungsten substrates.

In the examples presented below, CMP experiments were run using the procedures and experimental conditions given below.

### Parameters:

Å: angstrom(s)—a unit of length
BP: back pressure, in psi units
CMP: chemical mechanical planarization=chemical mechanical polishing
CS: carrier speed
DF: Down force: pressure applied during CMP, units psi
min: minute(s)
ml: milliliter(s)
mV: millivolt(s)
psi: pounds per square inch
PS: platen rotational speed of polishing tool, in rpm (revolution(s) per minute)
SF: polishing composition flow, ml/min
TEOS: silicon oxide films by Chemical Vapor Deposition (CVD) using tetraethyl orthosilicate as the precursor
Wt. %: weight percentage (of a listed component)

Removal Rate (RR)=(film thickness before polishing−film thickness after polishing)/polish time.

### Removal Rates and Selectivity

Tungsten Removal Rates: Measured tungsten removal rate at 3.0 psi down pressure of the CMP tool.
TEOS Removal Rates: Measured TEOS removal rate at a given down pressure. The down pressure of the CMP tool was 3.0 psi.
SiN Removal Rates: Measured SiN removal rate at a given down pressure. The down pressure of the CMP tool was 3.0 psi.

The CMP tool that was used in the examples is a AMAT 200 mm Mirra®, manufactured by Applied Materials, Inc. 3050 Bowers Avenue, Santa Clara, California, 95054. IC1010 polishing pad, supplied by Dow Chemicals was used on the platen for the polishing studies.

200 mm diameter silicon wafers coated with tungsten films, TEOS films, SiN films or tungsten containing SKW patterned structures were obtained from SKW Associate, Inc. 2920 Scott Blvd, Santa Clara, CA 95054. Polish time for blanket films was one minute. Tungsten removal rates were measured using sheet resistance measurement techniques. TEOS removal was measured using optical techniques. Patterned wafers were polished for time based on eddy current technique on the Ebara polisher. Polishing time for patterned wafer was 15 seconds past the end point identified by the eddy current end point technique. Patterned wafers were analyzed with a KLA Tencor P15 Profiler (large feature sizes) or an AFM tool (small feature sizes).

The polishing was performed using 111 RPM table speed, 113 RPM carrier speed, 200 ml/min slurry flow rate and at 3.0 psi downforce.

In the polishing process, a substrate (e.g., blanket W or patterned W wafers) was placed face-down on a polishing pad which was fixedly attached to a rotatable platen of a CMP polisher. In this manner, the substrate to be polished and planarized was placed in direct contact with the polishing pad. A wafer carrier system or polishing head was used to hold the substrate in place and to apply a downward pressure against the backside of the substrate during CMP processing while the platen and the substrate were rotated. The polishing composition (slurry) was applied (usually continuously) on the pad during CMP processing for effective removal of material and planarizing the substrate.

In the following working examples, four base CMP slurries (without the dicationic polymer) were made with 0.01 wt. % ferric nitrate (iron (III) nitrate), 0.08 wt. % malonic acid (stabilizer), 2.0 wt. % hydrogen peroxide, 0.1 wt. % glycine and 0.25 wt. %, and 0.3 wt. % one of the abrasive particles selected from Fuso PL-2C silica particles (base 1), amino-polyorganosiloxane (specifically 3-aminopropyl-methyldimethoxysilane)-coated silica particles as disclosed in WO 2023/178286 A1 in base 2 (20 mmol/g degree of functionalization and base particle size 80 nm), base 3 (48 mmol/g degree of functionalization and base particle size 80 nm), and base 4 (48 mmol/g degree of functionalization and base particle size 90 nm), in water with pH adjusted to 2.3 with nitric acid.

Various dicationic polymers were added to the base slurries to obtain the working slurries.

Effects of dicationic polymer on tungsten, TEOS, SiN removal rates, erosion and dishing were tested.

The removal rates and the selectivities of W:TEOS were shown in Table 1.

TABLE 1
Film Removal Rates and Film Selectivity

| | | W RR | TEOS RR | W:TEOS |
|---|---|---|---|---|
| Slurry | polymer | (Å/min) | (Å/min) | Selectivity |
| Base 1+ | Example 3 | 4270 | 29 | 147 |
| | (20 ppm) | | | |
| Base 1+ | Example 3 | 3628 | 30 | 121 |
| | (40 ppm) | | | |
| Base 1+ | Example 4-1 | 4266 | 28 | 152 |
| | (20 ppm) | | | |
| Base 1+ | Example 4-1 | 3272 | 30 | 109 |
| | (40 ppm) | | | |
| Base 2+ | Example 3 | 5871 | 10 | 587 |
| | (20 ppm) | | | |
| Base 2+ | Example 3 | 5466 | 10 | 547 |
| | (30 ppm) | | | |
| Base 2+ | Example 3 | 3766 | 9 | 418 |
| | (40 ppm) | | | |
| Base 2+ | Example 4-1 | 6103 | 14 | 436 |
| | (20 ppm) | | | |
| Base 2+ | Example 4-1 | 3569 | 13 | 275 |
| | (40 ppm) | | | |
| Base 2+ | Example 4-2 | 6270 | 13 | 482 |
| | (20 ppm) | | | |
| Base 2+ | Example 4-2 | 4872 | 18 | 271 |
| | (40 ppm) | | | |
| Base 3+ | Example 3 | 6119 | 28 | 219 |
| | (20 ppm) | | | |
| Base 3+ | Example 3 | 6341 | 40 | 159 |
| | (30 ppm) | | | |
| Base 3+ | Example 3 | 5188 | 29 | 179 |
| | (40 ppm) | | | |
| Base 4+ | Example 1 | 5982 | 21 | 285 |
| | (20 ppm) | | | |
| Base 4+ | Example 2 | 6086 | 24 | 254 |
| | (20 ppm) | | | |
| Base 4+ | Example 4-1 | 5273 | 23 | 229 |
| | (20 ppm) | | | |
| Base 4+ | Example 4-2 | 5578 | 24 | 232 |
| | (20 ppm) | | | |
| Base 4+ | Example 4-3 | 6073 | 22 | 276 |
| | (20 ppm) | | | |

As shown in Table 1, addition of a small amount of synthesized dicationic polymers offered high tungsten and very low TEOS removal rates, resulting in high selectivity.

Dishing of tungsten was tested on different arrays including, 0.18×0.18 micron array (tungsten line width/trench separated by dielectric line width/spacer in micron) (0.18/0.18 μm), 7×3 micron (7/3 μm) and 1×1 micron array (1/1 μm). The wafer was polished for 20 seconds additional time or over polishing (OP) time after the pattern wafer polish end point was detected by using eddy current measurement. W line dishing data is shown in Table 2.

TABLE 2
W Line Dishing [Å]

| Slurry | polymer | 0.18/0.18 μm | 7/3 μm | 1/1 μm |
|---|---|---|---|---|
| Base 1+ | Example 3 | 120 | 409 | 211 |
| | (20 ppm) | | | |
| Base 1+ | Example 3 | 86 | 295 | 170 |
| | (40 ppm) | | | |
| Base 1+ | Example 4-1 | 105 | 380 | 212 |
| | (20 ppm) | | | |
| Base 1+ | Example 4-1 | 65 | 251 | 151 |
| | (40 ppm) | | | |
| Base 2+ | Example 3 | 170 | 531 | 298 |
| | (20 ppm) | | | |
| Base 2+ | Example 3 | 150 | 474 | 219 |
| | (30 ppm) | | | |
| Base 2+ | Example 3 | 144 | 611 | 283 |
| | (40 ppm) | | | |
| Base 2+ | Example 4-1 | 179 | 488 | 262 |
| | (20 ppm) | | | |
| Base 2+ | Example 4-1 | 105 | 430 | 218 |
| | (40 ppm) | | | |
| Base 2+ | Example 4-2 | 190 | 497 | 283 |
| | (20 ppm) | | | |
| Base 2+ | Example 4-2 | 148 | 479 | 240 |
| | (40 ppm) | | | |
| Base 3+ | Example 3 | 233 | 520 | 296 |
| | (20 ppm) | | | |
| Base 3+ | Example 3 | 182 | 415 | 213 |
| | (30 ppm) | | | |
| Base 3+ | Example 3 | 170 | 553 | 302 |
| | (40 ppm) | | | |
| Base 4+ | Example 1 | 221 | 514 | 304 |
| | (20 ppm) | | | |
| Base 4+ | Example 2 | 221 | 594 | 271 |
| | (20 ppm) | | | |
| Base 4+ | Example 4-1 | 185 | 498 | 268 |
| | (20 ppm) | | | |
| Base 4+ | Example 4-2 | 197 | 522 | 282 |
| | (20 ppm) | | | |
| Base 4+ | Example 4-3 | 209 | 503 | 271 |
| | (20 ppm) | | | |

Dishing of lines typically increases for wider lines. In a typical tungsten CMP process, it is desirable that the tungsten dishing for wider line features lines is less than 1500 Angstroms [Å].

As shown in Table 2, addition of a small amount of synthesized dicationic polymers offered low W line dishing.

Erosion was tested on 7/3 μm, 1/1 μm and 50/50 μm arrays at 20 secs over-polish as shown in Table 3.

TABLE 3
Erosion [Å].

| Slurry | polymer | 7/3 μm | 1/1 μm | 50/50 μm |
|---|---|---|---|---|
| Base 1+ | Example 3 | 415 | 256 | 1 |
| | (20 ppm) | | | |
| Base 1+ | Example 3 | 302 | 170 | 58 |
| | (40 ppm) | | | |
| Base 1+ | Example 4-1 | 563 | 374 | 31 |
| | (20 ppm) | | | |
| Base 1+ | Example 4-1 | 353 | 224 | 77 |
| | (40 ppm) | | | |
| Base 2+ | Example 3 | 451 | 381 | 34 |
| | (20 ppm) | | | |
| Base 2+ | Example 3 | 433 | 305 | 87 |
| | (30 ppm) | | | |
| Base 2+ | Example 3 | 332 | 111 | 22 |
| | (40 ppm) | | | |
| Base 2+ | Example 4-1 | 480 | 326 | 82 |
| | (20 ppm) | | | |
| Base 2+ | Example 4-1 | 165 | 130 | 36 |
| | (40 ppm) | | | |
| Base 2+ | Example 4-2 | 495 | 365 | 71 |
| | (20 ppm) | | | |
| Base 2+ | Example 4-2 | 479 | 319 | 59 |
| | (40 ppm) | | | |
| Base 3+ | Example 3 | 596 | 348 | 22 |
| | (20 ppm) | | | |
| Base 3+ | Example 3 | 529 | 325 | 83 |
| | (30 ppm) | | | |
| Base 3+ | Example 3 | 415 | 191 | 21 |
| | (40 ppm) | | | |
| Base 4+ | Example 1 | 511 | 328 | 27 |
| | (20 ppm) | | | |
| Base 4+ | Example 2 | 854 | 501 | 4 |
| | (20 ppm) | | | |
| Base 4+ | Example 4-1 | 406 | 308 | 62 |
| | (20 ppm) | | | |
| Base 4+ | Example 4-2 | 437 | 317 | 56 |
| | (20 ppm) | | | |
| Base 4+ | Example 4-3 | 511 | 394 | 34 |
| | (20 ppm) | | | |

Erosion of arrays typically increases with an increase in pattern density. In a typical tungsten CMP process, it is desirable to have erosion on high density features such as 70% and 90% density <1000 Å.

As shown in Table 3, addition of a small amount of synthesized dicationic polymers offered low erosion.

While the principles of the invention have been described above in connection with preferred embodiments, it is to be clearly understood that this description is made only by way of example and not as a limitation of the scope of the invention. Rather, the ensuing detailed description of the preferred exemplary embodiments will provide those skilled in the art with an enabling description for implementing the preferred exemplary embodiments of the invention. Various changes may be made in the function and arrangement of elements without departing from the spirit and scope of the invention, as set forth in the appended claims.

1. A dicationic polymer or copolymer formed by at least one dicationic monomer comprising a structure of (I): 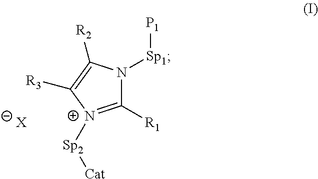
wherein:
P₁ denotes a polymerizable group selected from groups containing C═C double bonds;
Sp₁ and Sp₂ denote independently at each occurrence a spacer group or a single bond;
R₁, R₂, and R₃ are each independently H, or substituted or unsubstituted aliphatic aromatic moiety selected from the group consisting of (1) alkyl having <12 C atoms, or <4 C atoms atoms; and (2) phenyl, pyridinyl, pyrimidyl, furanyl or nitrogen-containing five-membered ring; and (3) combinations of (1) and (2);
Cat denotes in each occurrence a cationic group selected from the group consisting of ammonium-, guanidinium-, phosphonium-, and pyridinium-type group;
X⁻ denotes an anionic counterion selected from the group consisting of halide selected from the group consisting of F—, Cl—, Br—, and I—; BF₄—; PF₆—; carboxylate; malonate; citrate; carbonate; fumarate; MeOSO₃—; MeSO₃—; CF₃COO—; CF₃SO₃—; nitrate; and sulfate; and
the dicationic polymer or copolymer is formed by a polymerization method selected from the group consisting of free radical polymerization, reversible addition-fragmentation chain-transfer polymerization (RAFT), nitroxide-mediated polymerization (NMP), atomic transfer reaction polymerization (ATRP), ring opening polymerization (ROMP) and polycondensation reaction.

2. The dicationic polymer or copolymer according to claim 1, wherein the R₁, R₂, and R₃ are each independently H, or substituted or unsubstituted aliphatic aromatic moiety selected from the group consisting of CH₃ or CH₂—CH₃; pyridinylm, pyrimidyl, and combinations thereof.

3. (canceled)

4. (canceled)

5. The dicationic polymer or copolymer of claim 1; wherein the dicationic polymer or copolymer has a block-copolymer character.

6. The dicationic polymer or copolymer of claim 1; wherein the dicationic polymer or copolymer is selected from the group consisting of poly(3-ethyl-1-(3-(1-vinyl-1H-imidazol-3-ium-3-yl)propyl)-1H-imidzaol-3-ium dibromide), poly(3-(tributylphosphino)propyl)-1-vinyl-1H-imidzaol-3-ium dibromide), poly(3-(2-(trimethylammonio)ethyl)-1-vinyl-1H-imidzaol-3-ium-co-N-vinyl-pyrrolidone dibromide), and combinations thereof.

7. A chemical mechanical planarization composition comprising dicationic polymer or copolymer of claim 1.

8. A chemical mechanical planarization composition comprising:
an abrasive selected from the group consisting of inorganic oxide particles, metal oxide-coated inorganic oxide particles, organic polymer particles, metal oxide-coated organic polymer particles, and combinations thereof;
an activator;
an oxidizing agent;
an additive comprising the dicationic polymer or copolymer formed by at least one dicationic monomer comprising a structure of (I): 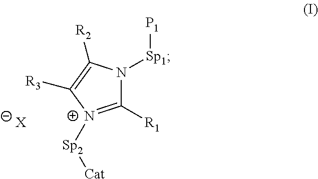
wherein:
P₁ denotes a polymerizable group selected from groups containing C═C double bonds;
Sp₁ and Sp₂ denote independently at each occurrence a spacer group or a single bond;
R₁, R₂, and R₃ are each independently H, or substituted or unsubstituted aliphatic aromatic moiety selected from the group consisting of (1) alkyl having <12 C atoms, or <4 C atoms atoms; and (2) phenyl, pyridinyl, pyrimidyl, furanyl or nitrogen-containing five-membered ring; and (3) combinations of (1) and (2);
Cat denotes in each occurrence a cationic group selected from the group consisting of ammonium-, guanidinium-, triazolium-, phosphonium-, pyridinium- and triazolium-type group;
X⁻ denotes an anionic counterion selected from the group consisting of halide selected from the group consisting of F—, Cl—, Br—, and I—; BF₄—; PF₆—; carboxylate; malonate; citrate; carbonate; fumarate; MeOSO₃—; MeSO₃—; CF₃COO—; CF₃SO₃—; nitrate; and sulfate; and
the dicationic polymer or copolymer is formed by a polymerization method selected from the group consisting of free radical polymerization, reversible addition-fragmentation chain-transfer polymerization (RAFT), nitroxide-mediated polymerization (NMP), atomic transfer reaction polymerization (ATRP), ring opening polymerization (ROMP) and polycondensation reaction;
water; and optionally at least one
a corrosion inhibitor;
a dishing reducing agent;
a stabilizer;
a pH adjusting agent.

9. The chemical mechanical planarization composition of claim 8, wherein the inorganic oxide particles are selected from the group consisting of ceria, colloidal silica, fumed silica, colloidal ceria, alumina, titania, zirconia, and combinations thereof; and are used in an amount ranging from 0.05 wt. % to 20 wt. %, or 0.01 wt. % to 10 wt. %;
the additive comprising the dicationic polymer or copolymer is selected from the group consisting of poly(3-ethyl-1-(3-(1-vinyl-1H-imidazol-3-ium-3-yl)propyl)-1H-imidzaol-3-ium dibromide), poly(3-(tributylphosphino)propyl)-1-vinyl-1H-imidzaol-3-ium dibromide), poly(3-(2-(trimethylammonio)ethyl)-1-vinyl-1H-imidzaol-3-ium dibromide), poly(3-(2-(trimethylammonio)ethyl)-1-vinyl-1H-imidzaol-3-ium-co-N-vinyl-pyrrolidone dibromide), and combinations thereof and the additive is used in an amount ranging from 0.00001 wt. % to 1.0 wt. %, or 0.00025 wt. % to 0.1 wt. %.

10. The chemical mechanical planarization composition of claim 8, wherein the additive comprising the dicationic polymer or copolymer the additive comprising the dicationic polymer or copolymer is selected from the group consisting of poly(3-ethyl-1-(3-(1-vinyl-1H-imidazol-3-ium-3-yl)propyl)-1H-imidzaol-3-ium dibromide), poly(3-(tributylphosphino)propyl)-1-vinyl-1H-imidzaol-3-ium dibromide), poly(3-(2-(trimethylammonio)ethyl)-1-vinyl-1H-imidzaol-3-ium dibromide), poly(3-(2-(trimethylammonio)ethyl)-1-vinyl-1H-imidzaol-3-ium-co-N-vinyl-pyrrolidone dibromide), and combinations thereof and the additive is used in an amount ranging from 0.00001 wt. % to 1.0 wt. %, or 0.00025 wt. % to 0.1 wt. %.

11. The chemical mechanical planarization composition of claim 8, wherein
the oxidizing agent is selected from the group consisting of peroxy compound selected from the group consisting of hydrogen peroxide, urea peroxide, peroxyformic acid, peracetic acid, propaneperoxoic acid, substituted or unsubstituted butaneperoxoic acid, hydroperoxy-acetaldehyde, potassium periodate, ammonium peroxymonosulfate; and non-per-oxy compound selected from the group consisting of iron (III) nitrate, KClO₄, KBrO₄, KMnO₄; and
combinations thereof; and the oxidizing agent is used in an amount ranging from 0.1 wt. % to 20 wt. %, or 0.5 wt. % to 10 wt. %;
the activator is selected from the group consisting of (1) inorganic oxide particle with transition metal coated onto its surface; and the transition metal is selected from the group consisting of Fe, Cu, Mn, Co, Ce, and combinations thereof; (2) soluble catalyst selected from the group consisting of iron (III) nitrate, ammonium iron (III) oxalate trihydrate, iron (III) citrate tribasic monohydrate, iron (III) acetylacetonate and ethylenediamine tetraacetic acid, iron (III) sodium salt hydrate; (3) a metal compound having multiple oxidation states selected from the group consisting of Ag, Co, Cr, Cu, Fe, Mo, Mn, Nb, Ni, Os, Pd, Ru, Sn, Ti, V; and
combinations thereof; and the activator is used in an amount ranging from 0.00001 wt. % to 5.0 wt. %, or 0.0005 wt. % to 1.0 wt. %.

12. (canceled)

13. The chemical mechanical planarization composition of claim 8, wherein the chemical mechanical planarization composition further comprises at least one of
the corrosion inhibitor selected from the group consisting of 1,2,3-triazole, 1,2,4-triazole, 1,2,3-benzotriazole, 5-methylbenzotriazole, benzotriazole, 1-hydroxybenzotriazole, 4-hydroxybenzotriazole, 3-amino-1,2,4-triazole, 4-amino-4H-1,2,4-triazole, 5 amino triazole, benzimidazole, 2,1,3-benzothiadiazole, triazinethiol, triazinedithiol, and triazinetrithiol, pyrazoles, imidazoles, isocyanurate such as 1,3,5-Tris(2-hydroxyethyl), and combinations thereof; and the corrosion inhibitor is used in an amount ranging from less than 1.0 wt. %, or less than 0.5 wt. %;
the dishing reducing agent selected from the group consisting of sarcosinate and related carboxylic compounds; hydrocarbon substituted sarcosinate; amino acids; organic polymers and copolymers having molecules containing ethylene oxide repeating units, such as polyethylene oxide (PEO); ethoxylated surfactants; nitrogen containing heterocycles without nitrogen-hydrogen bonds; sulfide; oxazolidine or mixture of functional groups in one compound; nitrogen containing compounds having three or more carbon atoms that form alkylammonium ions; amino alkyls having three or more carbon atoms; polymeric corrosion inhibitor comprising a repeating group of at least one nitrogen-containing heterocyclic ring or a tertiary or quaternary nitrogen atom; dicationic amine compound; cyclodextrin compound; polyethyleneimine compound; glycolic acid; chitosan; sugar alcohols; polysaccharides; alginate compound; and sulfonic acid polymer; and
combinations thereof; and the dishing reducing agent is used in an amount ranging from 0.001 wt. % to 2.0 wt. %, or 0.005 wt. % to 1.5 wt. %; and
the stabilizer selected from the group consisting of adipic acid, phthalic acid, citric acid, malonic acid, orthophthalic acid; phosphoric acid; substituted or unsubstituted phosphonic acids; nitriles; and combinations thereof; and the stabilizer is used in an amount ranging from 0.0001 to 5 wt. %, 0.00025 to 2 wt. %, or 0.0005 to 1 wt. %.

14. (canceled)

15. The chemical mechanical planarization composition of claim 8, wherein pH of the composition is between 1 and 7, or 1.5 and 4; and the chemical mechanical planarization composition optionally comprises a pH adjusting agent selected from the group consisting of (a) nitric acid, sulfuric acid, tartaric acid, succinic acid, citric acid, malic acid, malonic acid, various fatty acids, various polycarboxylic acids, and mixtures thereof to lower the pH; and (b) potassium hydroxide, sodium hydroxide, ammonia, tetraethylammonium hydroxide, ethylenediamine, piperazine, polyethyleneimine, modified polyethyleneimine, and mixtures thereof to raise the pH.

16. (canceled)

17. (canceled)

18. The chemical mechanical planarization composition of claim 8, wherein
the abrasive is silica particles;
the additive comprising the dicationic polymer or copolymer is selected from the group consisting of poly(3-ethyl-1-(3-(1-vinyl-1H-imidazol-3-ium-3-yl)propyl)-1H-imidzaol-3-ium dibromide), poly(3-(tributylphosphino)propyl)-1-vinyl-1H-imidzaol-3-ium dibromide), poly(3-(2-(trimethylammonio)ethyl)-1-vinyl-1H-imidzaol-3-ium dibromide), poly(3-(2-(trimethylammonio)ethyl)-1-vinyl-1H-imidzaol-3-ium-co-N-vinyl-pyrrolidone dibromide), and combinations thereof;
the activator is iron (III) nitrate; and
the oxidizer is hydrogen peroxide.

19. The chemical mechanical planarization composition of claim 8, wherein the chemical mechanical planarization composition comprises silica particles; poly(vinyl-3-ethyl-1H-imidazol-3-ium-co-tributyl-(4-vinylbenzyl)-phosphonium) bromide chloride, iron (III) nitrate, malonic acid, hydrogen peroxide, and water; the pH of the composition is between 1.5 and 4.

20. A polishing method for chemical mechanical planarization of a semiconductor substrate comprising at least one surface containing tungsten, comprising the steps of:
a) providing a polishing pad;
b) providing the chemical mechanical polishing composition of claim 8;
wherein pH of the composition is between 1 and 7, or 1.5 and 4; and
c) polishing the at least one surface containing tungsten with the chemical mechanical planarization composition.

21. The polishing method of claim 20, wherein the chemical mechanical planarization composition has the inorganic oxide particles selected from the group consisting of ceria, colloidal silica, fumed silica, colloidal ceria, alumina, titania, zirconia, and combinations thereof; and are used in an amount ranging 0.05 wt. % to 20 wt. %, or 0.01 wt. % to 10 wt. %;
the additive comprising the dicationic polymer or copolymer selected from the group consisting of poly(3-ethyl-1-(3-(1-vinyl-1H-imidazol-3-ium-3-yl)propyl)-1H-imidzaol-3-ium dibromide), poly(3-(tributylphosphino)propyl)-1-vinyl-1H-imidzaol-3-ium dibromide), poly(3-(2-(trimethylammonio)ethyl)-1-vinyl-1H-imidzaol-3-ium dibromide), poly(3-(2-(trimethylammonio)ethyl)-1-vinyl-1H-imidzaol-3-ium-co-N-vinyl-pyrrolidone dibromide), and combinations thereof and the additive is used in an amount ranging from 0.00001 wt. % to 1.0 wt. %, or 0.00025 wt. % to 0.1 wt. %;
the oxidizing agent selected from the group consisting of peroxy compound selected from the group consisting of hydrogen peroxide, urea peroxide, peroxyformic acid, peracetic acid, propaneperoxoic acid, substituted or unsubstituted butaneperoxoic acid, hydroperoxy-acetaldehyde, potassium periodate, ammonium peroxymonosulfate; and non-per-oxy compound selected from the group consisting of iron (III) nitrate, KClO₄, KBrO₄, KMnO₄; and
combinations thereof; and the oxidizing agent is used in an amount ranging from 0.1 wt. % to 20 wt. %, or 0.5 wt. % to 10 wt. %; and
the activator selected from the group consisting of (1) inorganic oxide particle with transition metal coated onto its surface; and the transition metal is selected from the group consisting of Fe, Cu, Mn, Co, Ce, and combinations thereof; (2) soluble catalyst selected from the group consisting of iron (III) nitrate, ammonium iron (III) oxalate trihydrate, iron (III) citrate tribasic monohydrate, iron (III) acetylacetonate and ethylenediamine tetraacetic acid, iron (III) sodium salt hydrate; (3) a metal compound having multiple oxidation states selected from the group consisting of Ag, Co, Cr, Cu, Fe, Mo, Mn, Nb, Ni, Os, Pd, Ru, Sn, Ti, V; and combinations thereof; and the activator is used in an amount ranging from 0.00001 wt. % to 5.0 wt. %, or 0.0005 wt. % to 1.0 wt. %.

22. (canceled)

23. (canceled)

24. (canceled)

25. The polishing method of claim 20, wherein the chemical mechanical planarization composition further comprises at least one of the corrosion inhibitor is selected from the group consisting of 1,2,3-triazole, 1,2,4-triazole, 1,2,3-benzotriazole, 5-methylbenzotriazole, benzotriazole, 1-hydroxybenzotriazole, 4-hydroxybenzotriazole, 3-amino-1,2,4-triazole, 4-amino-4H-1,2,4-triazole, 5 amino triazole, benzimidazole, 2,1,3-benzothiadiazole, triazinethiol, triazinedithiol, and triazinetrithiol, pyrazoles, imidazoles, isocyanurate such as 1,3,5-Tris(2-hydroxyethyl), and combinations thereof; and the corrosion inhibitor is used in an amount ranging from less than 1.0 wt. %, or less than 0.5 wt. %;
the dishing reducing agent selected from the group consisting of sarcosinate and related carboxylic compounds; hydrocarbon substituted sarcosinate; amino acids; organic polymers and copolymers having molecules containing ethylene oxide repeating units, such as polyethylene oxide (PEO); ethoxylated surfactants; nitrogen containing heterocycles without nitrogen-hydrogen bonds; sulfide; oxazolidine or mixture of functional groups in one compound; nitrogen containing compounds having three or more carbon atoms that form alkylammonium ions; amino alkyls having three or more carbon atoms; polymeric corrosion inhibitor comprising a repeating group of at least one nitrogen-containing heterocyclic ring or a tertiary or quaternary nitrogen atom; dicationic amine compound; cyclodextrin compound; polyethyleneimine compound; glycolic acid; chitosan; sugar alcohols; polysaccharides; alginate compound; and sulfonic acid polymer; and
combinations thereof; and the dishing reducing agent is used in an amount ranging from 0.001 wt. % to 2.0 wt. %, or 0.005 wt. % to 1.5 wt. %; and
the stabilizer selected from the group consisting of adipic acid, phthalic acid, citric acid, malonic acid, orthophthalic acid; phosphoric acid; substituted or unsubstituted phosphonic acids; nitriles; and combinations thereof; and the stabilizer is used in an amount ranging from 0.0001 to 5 wt. %, 0.00025 to 2 wt. %, or 0.0005 to 1 wt. %.

26. (canceled)

27. (canceled)

28. (canceled)

29. (canceled)

30. (canceled)

31. The polishing method of claim 20, wherein the chemical mechanical planarization composition comprises silica particles; iron (III) nitrate; malonic acid; hydrogen peroxide; poly(vinyl-3-ethyl-1H-imidazol-3-ium-co-tributyl-(4-vinylbenzyl)-phosphonium) bromide chloride, and water; the pH of the composition is between 1.5 and 4.

32. The polishing method of claim 20, wherein at least one surface containing tungsten comprises a dishing topography of less than 2000 or less than 1000 Angstroms and an erosion topography of less than 2000 or less than 1000 Angstroms

33. A system for chemical mechanical planarization of a semiconductor substrate comprising at least one surface containing tungsten, comprising:
a) a polishing pad; and
b) the chemical mechanical polishing composition of claim 8,
and
wherein the at least one surface containing tungsten is in contact with the polishing pad and the chemical mechanical planarization composition polishing the at least one surface containing tungsten with the chemical mechanical planarization composition.

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. The chemical mechanical planarization composition of claim 7, wherein
the dicationic polymer or copolymer is selected from the group consisting of poly(3-ethyl-1-(3-(1-vinyl-1H-imidazol-3-ium-3-yl)propyl)-1H-imidzaol-3-ium dibromide), poly(3-(tributylphosphino)propyl)-1-vinyl-1H-imidzaol-3-ium dibromide), poly(3-(2-(trimethylammonio)ethyl)-1-vinyl-1H-imidzaol-3-ium dibromide), poly(3-(2-(trimethylammonio)ethyl)-1-vinyl-1H-imidzaol-3-ium-co-N-vinyl-pyrrolidone dibromide), and combinations thereof;
the activator is iron (III) nitrate; and
the oxidizer is hydrogen peroxide.
